(19) United States
(12) Patent Application Publication
(10) Pub. No.: US 2015/0092274 A1
(43) Pub. Date: Apr. 2, 2015

(54) OPTICAL FILTER DEVICE, OPTICAL MODULE, ELECTRONIC DEVICE, AND MEMS DEVICE

(71) Applicant: Seiko Epson Corporation, Tokyo (JP)

(72) Inventors: Yasushi MATSUNO, Matsumoto (JP); Daisuke SAITO, Matsumoto (JP); Hideo IMAI, Shimosuwa (JP); Shigemitsu KOIKE, Suwa (JP)

(21) Appl. No.: 14/493,820

(22) Filed: Sep. 23, 2014

(30) Foreign Application Priority Data
Sep. 27, 2013 (JP) 2013-201048

(51) Int. Cl. G02B 26/00; B81B 5/00; G02B 5/28

(52) U.S. Cl. CPC G02B 26/001; G02B 5/284; B81B 5/00
USPC 359/578; 359/589

(57) ABSTRACT

An optical filter device includes a wavelength variable interference filter, a housing that stores the wavelength variable interference filter, and a bonding member that fixes a movable substrate to the housing. The housing includes a fixing portion that comes into contact with the bonding member, the fixing portion includes a pedestal fixing surface (first surface) facing a portion of a surface of the movable substrate, a sidewall fixing surface (second surface), continuous with a portion of a periphery of the pedestal fixing surface, which faces a lateral side of the movable substrate, and an intersection surface (third surface) continuous from a remaining portion in a periphery of the pedestal fixing surface in a direction away from the movable substrate, and the bonding member is provided between the substrate surface and the pedestal fixing surface, and between the lateral side and the sidewall fixing surface.

### BACKGROUND

1. Technical Field

The present invention relates to an optical filter device, an optical module, an electronic device, and a MEMS device.

2. Related Art

Hitherto, various types of MEMS (Micro Electro Mechanical Systems) elements such as an interference filter having reflective films oppositely disposed, respectively, on the surfaces of a pair of substrates facing each other with a predetermined gap interposed therebetween, a mirror element having a reflective film disposed on a substrate, and a piezoelectric vibrating element having a piezoelectric substance such as a quartz crystal vibrating piece disposed on a substrate have been known. In addition, a MEMS device having such a MEMS element stored within a storage container is known (see, for example, JP-A-2008-70163).

JP-A-2008-70163 discloses an infrared gas detector (optical filter device) provided with a package (housing) having a plate-like pedestal and a cylindrical cap. This housing is configured such that a circumferential portion of a base substrate and cylindrical one end of the cap are welded or bonded and connected to each other, and is provided with a space for storing a Fabry-Perot filter (interference filter) between the base substrate and the cap. This interference filter is bonded and fixed at the lower surface side of the substrate constituting the interference filter.

As described above, the interference filter disclosed in JP-A-2008-70163 is bonded and fixed at the lower surface side of the substrate, and adheres closely to an adhesive in a surface direction intersecting the thickness direction of the substrate. The adhesive, generally, has low viscosity due to heat provided during curing, and wets and spreads on a wide region on the lower surface side of the substrate. Thereafter, the adhesive is cured and contracted, and thus stress associated with the contraction of the adhesive is applied to the wide region of the substrate. For this reason, the lower surface of the substrate receives stress centering on a bonding position along a surface direction, and thus there is a concern that the substrate may bend. When the substrate bends, reflective films provided on the substrate are distorted, or a size of a gap between the reflective films changes, which results in a deterioration in the spectral accuracy of the interference filter.

On the other hand, when a fixed area due to an adhesive is reduced, there is a concern that the interference filter may deviate from the housing when a vibration or an impact is applied.

In various types of MEMS devices mentioned above, when bending occurs in the substrate constituting a MEMS element, the performance of the MEMS element deteriorates due to the influence of the bending. On the other hand, there is a similar problem in that the MEMS element falls off from the housing by reducing the fixed area.

### SUMMARY

An advantage of some aspects of the invention is to provide an optical filter device, an optical module, an electronic device, and a MEMS device which are capable of achieving both the prevention of performance deterioration and the prevention of falling off from a housing.

An aspect of the invention is directed to an optical filter device including: an interference filter that includes a first reflective film and a second reflective film facing the first reflective film; a housing that stores the interference filter; and a bonding member that fixes the interference filter to the housing, wherein the housing includes a first surface which is located so as to face one surface of the interference filter, a second surface, continuous with the first surface, which is located so as to face another surface intersecting the one surface of the interference filter, and a third surface, continuous from the first surface, which is located in a direction away from the interference filter, and the bonding member is disposed between the one surface and the first surface, and between the another surface and the second surface.

The optical filter device includes an interference filter that includes a first reflective film, a second reflective film facing the first reflective film, and a substrate provided with any of the first reflective film and the second reflective film, a housing having an internal space capable of storing the interference filter, and a bonding member that fixes a substrate lateral side along a thickness direction of the substrate and a substrate surface intersecting the substrate lateral side to the housing. The housing includes a first surface facing the substrate surface, a second surface, continuous with a portion of a periphery of the first surface, which faces the substrate lateral side, and a third surface continuous from a remaining portion in a periphery of the first surface in a direction away from the substrate. The bonding member is provided extending between the substrate surface and the first surface, and between the substrate lateral side and the second surface.

Here, the bonding member includes various types of adhesive, more specifically, a thermosetting resin, a UV curing resin, and the like.

In the aspect of the invention, the housing includes the first surface facing the substrate surface of the substrate, the second surface continuous with a portion of the first surface so as to face the substrate lateral side, and the third surface continuous from a remaining portion which is not continuous with the second surface in the vicinity of the first surface in a direction away from the substrate. Meanwhile, a description is given in which the first surface, the second surface and the third surface constitute a fixing portion that comes into contact with the bonding member. The bonding member is provided extending between the substrate surface and the first surface of the fixing portion, and between the substrate lateral side and the second surface of the fixing portion, and bonds the substrate and the fixing portion of the housing.

In such a configuration, even when the bonding member has flowability before curing, the flow of the bonding member stops at the edge portion between the first surface and the third surface of the fixing portion, and the bonding member wets and spreads to the second surface side. Therefore, the bonding member comes into contact with a position facing the first surface of the fixing portion on the substrate surface and a position facing the second surface of the fixing portion on the substrate lateral side. That is, the wetting and spreading of the bonding member can be regulated by a stepped difference of a boundary between the first surface and the third surface of the fixing portion. Thereby, it is possible to suppress an increase in contraction stress of the bonding member due to the extension of an area in which the bonding member and the substrate surface come into contact with each other. As a result, it is possible to suppress a deterioration in spectral performance of the interference filter due to an increase in the contraction stress and thus the bending of the substrate.

In addition, the bonding member wets and spreads between the substrate lateral side and the second surface of the fixing portion, but the lateral side of the substrate has a higher rigidity to bending than the surface of the substrate, and thus is not likely to be influenced by contraction stress.

Further, since the bonding area can be increased, as compared to a case where the bonding member is provided only between the substrate lateral side and the second surface of the fixing portion, or a case where the bonding member is provided only between the substrate surface and the first surface of the fixing portion, it is possible to increase a bonding strength to that extent, and thus a fixing force capable of preventing the substrate from falling off due to a vibration or the like is obtained.

In the optical filter device of the aspect of the invention described above, it is preferable that the housing include a groove portion that surrounds a remaining portion in a periphery of the first surface, and that the third surface is a lateral side on the first surface side in the groove portion.

In this configuration, the groove portion is formed so as to surround the first surface of the fixing portion, and the third surface is formed by one lateral side of the groove portion. In such a configuration, as compared to a configuration where a through-hole is provided, for example, so as to surround the first surface of the fixing portion, the sealability of a storage space that stores the interference filter is excellent, and thus an airtight space can be easily formed.

In the optical filter device of the aspect of the invention described above, it is preferable that a distance between the substrate surface and a bottom of the groove portion is larger than a distance between the substrate lateral side and the second surface.

In this configuration, when the bonding member wets and spreads, the bonding member has a tendency to wet and spread between the substrate lateral side and the second surface of the fixing portion having a smaller distance than that between the substrate surface and the bottom of the groove portion due to a capillary phenomenon. Therefore, it is possible to more reliably prevent the bonding member from wetting and spreading onto the substrate surface, and to more reliably prevent the substrate from bending.

In the optical filter device of the aspect of the invention described above, it is preferable that the substrate lateral side include a first lateral side having a planar shape and a second lateral side having a planar shape, continuous with the first lateral side, which intersects the first lateral side, and the bonding member is provided extending over the first lateral side and the second lateral side.

Here, the second surface of the fixing portion has surfaces facing the first lateral side and the second lateral side of the substrate lateral side, respectively, and the bonding member is provided between the first lateral side and second lateral side, and the first surface and the second surface of the fixing portion which face the first lateral side and second lateral side, respectively.

In the configuration described above, the bonding member is provided extending over the first lateral side and the second lateral side of the substrate lateral side which are continuous with each other and are not flush with each other. According to this, in a state where the bonding member is disposed from the first lateral side of the substrate lateral side, through a corner at which the first lateral side and the second lateral side intersect each other, to the second lateral side, the substrate is pressed against the second surface and the third surface of the fixing portion, thereby allowing the substrate to be fixed to the housing by a simple operation.

In addition, since the fixing portion fixes the substrate to the housing at each of the first surface and the second surface which are two lateral sides intersecting each other, it is possible to increase a fixing force of the substrate to the housing.

In the optical filter device of the aspect of the invention described above, it is preferable that the interference filter include a first substrate which is provided with the first reflective film and a second substrate, facing the first substrate, which is provided with the second reflective film, and that the bonding member fixe any of the first substrate and the second substrate to the housing.

In this configuration, the interference filter includes the first substrate and the second substrate. The first substrate and the second substrate are disposed so as to face each other. In such a configuration, when the bonding member is provided throughout the lateral sides of both the first substrate and the second substrate, there is a concern that since stress from the bonding member is applied in a direction in which the first substrate and the second substrate are brought close to each other or kept away from each other, the first substrate and the second substrate may not be able to be maintained in parallel to each other, or a gap size between the reflective films may fluctuate.

On the other hand, in the configuration described above, the bonding member is provided so as to fix any of the first substrate and the second substrate to the housing, and thus it is possible to maintain the parallel between the substrates, and to suppress a fluctuation in the gap size between the reflective films. Therefore, it is possible to suppress a deterioration in the spectral accuracy of the interference filter due to the inability of the parallel between the substrates to be maintained or a fluctuation in the accuracy of the gap size, and to maintain spectral accuracy.

In the optical filter device of the aspect of the invention described above, it is preferable that any one of the first substrate and the second substrate include a protruding portion that protrudes to the other substrate in a planar view when seen from a substrate thickness direction, the first surface overlap at least a portion of the protruding portion in the planar view, and that the bonding member be provided extending between the substrate surface and the first surface in the protruding portion, and between the substrate lateral side and the second surface in the protruding portion.

In this configuration, at least one of a pair of substrates includes the protruding portion that protrudes to the other substrate in the planar view, and the first surface of the fixing portion is located at a position overlapping the protruding portion in the planar view. The protruding portion and the facing portion and the first surface of the fixing portion are fixed to each other by the bonding member. In this manner, the protruding portion and the first surface of the fixing portion are configured to overlap each other in the planar view, and the bonding member is provided at a position where a pair of substrates do not face each other, thereby allowing only any one of a pair of substrates to be fixed to the bonding member more reliably.

In the optical filter device of the aspect of the invention described above, it is preferable that the protruding portion include a connection terminal which is electrically connected to a terminal on the housing side provided to the housing.

In this configuration, the protruding portion is an electronic component portion. In such a configuration, even when an impact is applied to the optical filter device, or the optical filter device is vibrated by the driving of the optical filter device, it is possible to suppress the vibration of the electronic component portion provided with the connection terminal. Therefore, it is possible to prevent a disadvantage such as the disconnection of a wiring between the connection terminal and the terminal on the housing side.

In the optical filter device of the aspect of the invention described above, it is preferable that the second substrate include a movable portion which is provided with the second reflective film and a holding portion that replaceably holds the movable portion in a thickness direction of the second substrate, and that the bonding member fixe the first substrate to the housing.

In this configuration, the second substrate includes the holding portion that replaceably holds the movable portion in the thickness direction. In such an interference filter, the movable portion is replaced by the holding portion in the thickness direction, thereby allowing the size of a gap (hereinafter, also referred to as the gap size) formed between the first reflective film and the second reflective film to be changed. On the other hand, in such an interference filter, since the second substrate is provided with the holding portion, the rigidity of the second substrate in the thickness direction of the substrate becomes smaller than the rigidity of the first substrate in the thickness direction of the substrate. Therefore, when the second substrate is provided with the bonding member, there is a concern that the second substrate may bend due to stress of the bonding member. On the other hand, in the configuration described above, the first substrate having a rigidity larger than the second substrate is provided with the bonding member, and thus it is possible to prevent bending from being generated in the substrate, and to prevent the spectral accuracy of the interference filter from deteriorating.

Another aspect of the invention is directed to an optical module including: an interference filter that includes a first reflective film and a second reflective film facing the first reflective film; a housing that stores the interference filter; a bonding member that fixes the interference filter to the housing; and a detection unit that detects light extracted by the interference filter, wherein the housing includes a first surface which is located so as to face one surface of the interference filter, a second surface, continuous with the first surface, which is located so as to face another surface intersecting the one surface of the interference filter, and a third surface, continuous from the first surface, which is located in a direction away from the interference filter, and the bonding member is disposed between the one surface and the first surface, and between the another surface and the second surface.

The optical module includes an interference filter that includes a first reflective film, a second reflective film facing the first reflective film, and a substrate provided with any of the first reflective film and the second reflective film, a housing having an internal space capable of storing the interference filter, a bonding member that fixes the substrate to the housing, and a detection unit that detects light extracted by the interference filter. The housing includes a fixing portion with which the bonding member comes into contact, and the fixing portion includes a first surface facing a portion of a substrate surface intersecting a thickness direction of the substrate, a second surface, continuous with a portion of a periphery of the first surface, which faces a substrate lateral side along the thickness direction of the substrate, and a third surface continuous from a remaining portion in a periphery of the first surface in a direction away from the substrate. The bonding member is provided extending between the substrate surface and the first surface, and between the substrate lateral side and the second surface.

In the aspect of the invention, the housing includes a fixing portion formed similarly to the above-mentioned aspect, and the bonding member is provided extending between the substrate, and the first surface and the second surface. Thereby, similarly to the above-mentioned aspect, it is possible to obtain a desired fixing force while suppressing the bending of the substrate due to stress from the bonding member. Therefore, it is possible to provide an optical module which is capable of preventing performance from deteriorating and has high reliability for an impact or a vibration.

Still another aspect of the invention is directed to an electronic device including: an interference filter that includes a first reflective film and a second reflective film facing the first reflective film; a housing that stores the interference filter; a bonding member that fixes the interference filter to the housing; and a control unit that controls the interference filter, wherein the housing includes a first surface which is located so as to face one surface of the interference filter, a second surface, continuous with the first surface, which is located so as to face another surface intersecting the one surface of the interference filter, and a third surface, continuous from the first surface, which is located in a direction away from the interference filter, and the bonding member is disposed between the one surface and the first surface, and between the another surface and the second surface.

The electronic device includes an interference filter that includes a first reflective film, a second reflective film facing the first reflective film, and a substrate provided with any of the first reflective film and the second reflective film, a housing having an internal space capable of storing the interference filter, a bonding member that fixes the substrate to the housing, and a control unit that controls the interference filter. The housing includes a fixing portion with which the bonding member comes into contact, and the fixing portion includes a first surface facing a portion of a substrate surface intersecting a thickness direction of the substrate, a second surface, continuous with a portion of a periphery of the first surface, which faces a substrate lateral side along the thickness direction of the substrate, and a third surface continuous from a remaining portion in a periphery of the first surface in a direction away from the substrate. The bonding member is provided extending between the substrate surface and the first surface, and between the substrate lateral side and the second surface.

In the aspect of the invention, the housing includes a fixing portion formed similarly to the above-mentioned aspect, and the bonding member is provided extending between the substrate, and the first surface and the second surface. Thereby, similarly to the above-mentioned aspect, it is possible to obtain a desired fixing force while suppressing the bending of the substrate due to stress from the bonding member. Therefore, it is possible to provide an electronic device capable of preventing performance from deteriorating and has high reliability for an impact or a vibration.

Yet another aspect of the invention is directed to a MEMS device including: a MEMS element; a housing that stores the MEMS element; and a bonding member that fixes the substrate to the housing, wherein the housing includes a first surface which is located so as to face one surface of the MEMS element, a second surface, continuous with the first surface, which is located so as to face another surface intersecting the one surface of the MEMS element, and a third surface, continuous from the first surface, which is located in a direction away from the MEMS element, and the bonding member is disposed between the one surface and the first surface, and between the another surface and the second surface.

The MEMS device includes a MEMS element provided with a substrate, a housing having an internal space capable of storing the MEMS element, and a bonding member that fixes the substrate to the housing. The housing includes a fixing portion with which the bonding member comes into contact, and the fixing portion includes a first surface facing a portion of a substrate surface intersecting a thickness direction of the substrate, a second surface, continuous with a portion of a periphery of the first surface, which faces a substrate lateral side along the thickness direction of the substrate, and a third surface continuous from a remaining portion in a periphery of the first surface in a direction away from the substrate. The bonding member is provided extending between the substrate surface and the first surface, and between the substrate lateral side and the second surface.

In the aspect of the invention, the housing includes the fixing portion formed similarly to the above-mentioned aspect, and the bonding member is provided extending between the substrate, and the first surface and the second surface of the fixing portion. Thereby, similarly to the above-mentioned aspect, it is possible to prevent the substrate from bending due to stress from the bonding member, and to prevent the performance of the MEMS element from deteriorating due to the bending of the MEMS element. Further, since a bonding area can be increased while regulating wetting and spreading onto the substrate surface, it is possible to increase a bonding strength, and to obtain a fixing force capable of preventing the substrate from falling off due to a vibration or the like. Therefore, it is possible to provide a MEMS element which is capable of preventing performance from deteriorating and has high reliability for an impact or a vibration.

### BRIEF DESCRIPTION OF THE DRAWINGS

The invention will be described with reference to the accompanying drawings, wherein like numbers reference like elements.

FIG. 1 is a cross-sectional view illustrating a schematic configuration of an optical filter device according to a first embodiment of the invention.

FIG. 2 is a plan view illustrating a schematic configuration of the optical filter device according to the embodiment.

FIG. 3 is a cross-sectional view illustrating a schematic configuration of a wavelength variable interference filter according to the embodiment.

FIG. 4 is a cross-sectional view illustrating a schematic configuration of an optical filter device according to a second embodiment.

FIG. 5 is a plan view illustrating a schematic configuration of the optical filter device according to the embodiment.

FIG. 6 is a block diagram illustrating a schematic configuration of a colorimeter according to a third embodiment.

FIG. 7 is a plan view illustrating a schematic configuration of a modification example of the optical filter device according to the invention.

FIG. 8 is a cross-sectional view illustrating a schematic configuration of a modification example of the optical filter device according to the invention.

FIG. 9 is a schematic diagram illustrating a gas detector which is an example of an electronic device according to the invention.

FIG. 10 is a block diagram illustrating a configuration of a control system of the gas detector of FIG. 9.

FIG. 11 is a diagram illustrating a schematic configuration of a food analyzer which is an example of the electronic device according to the invention.

FIG. 12 is a schematic diagram illustrating a schematic configuration of a spectroscopic camera which is an example of the electronic device according to the invention.

### DESCRIPTION OF EXEMPLARY EMBODIMENTS

### First Embodiment

Hereinafter, a first embodiment of the invention will be described with reference to the accompanying drawings.

### Configuration of Optical Filter Device

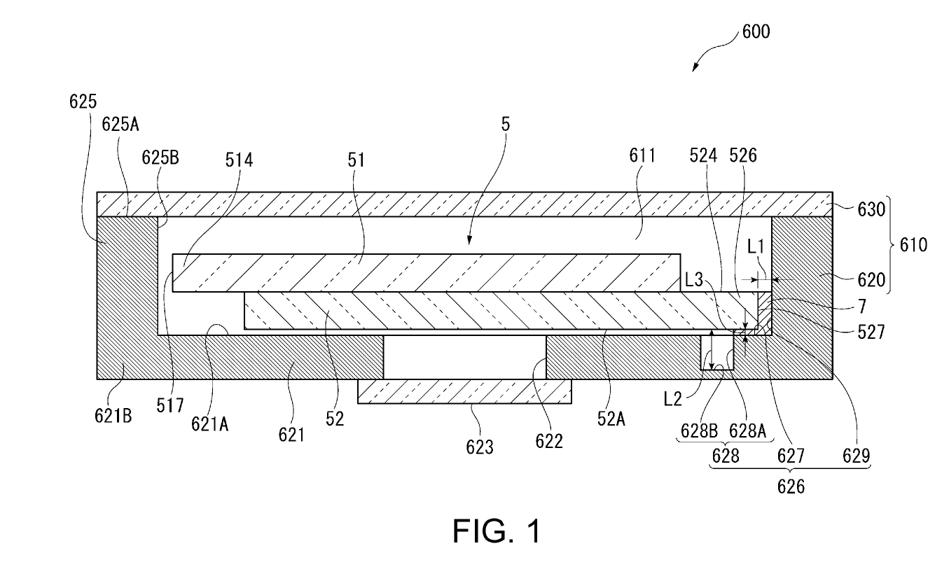

FIG. 1 is a cross-sectional view illustrating a schematic configuration of an optical filter device 600 which is an embodiment of an optical filter device according to the invention.

The optical filter device 600 is a device that extracts light having a predetermined target wavelength from incident light to be tested and emits the extracted light, and includes a housing 610 and a wavelength variable interference filter 5 which is stored inside the housing 610. Such an optical filter device 600 can be incorporated into, for example, an optical module such as a colorimetric sensor, or an electronic device such as a colorimeter and a gas analyzer. Meanwhile, the configuration of an optical module or an electronic device including the optical filter device 600 will be described later in detail.

### Configuration of Wavelength Variable Interference Filter

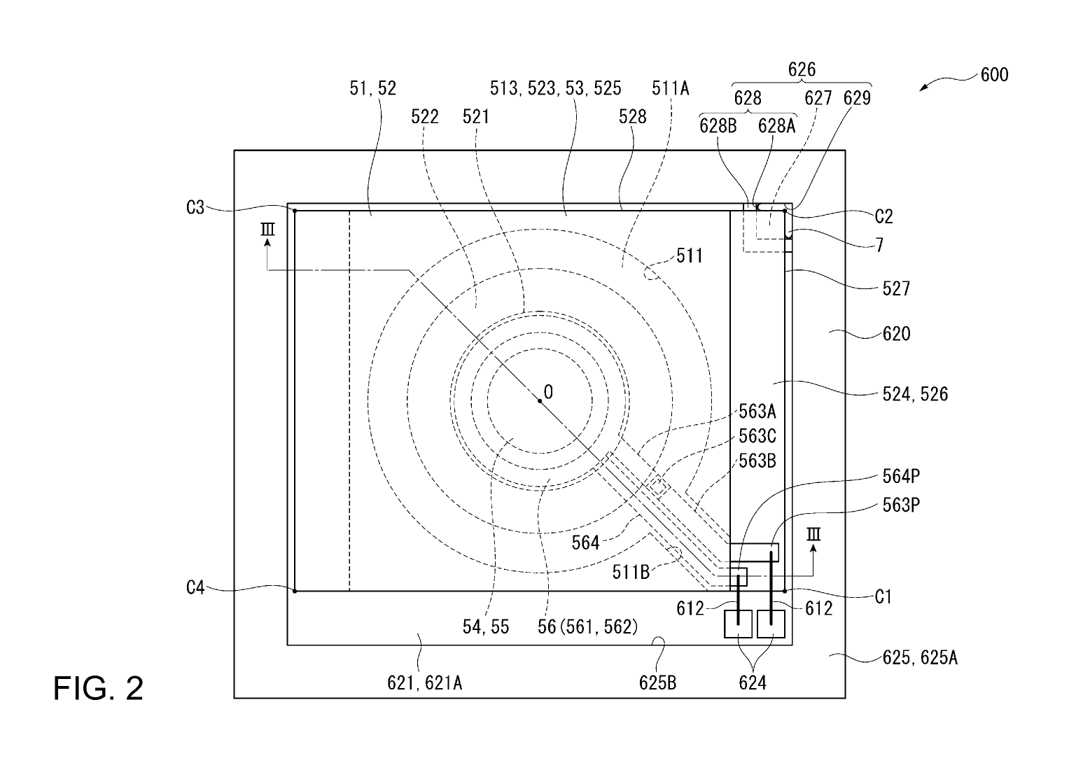

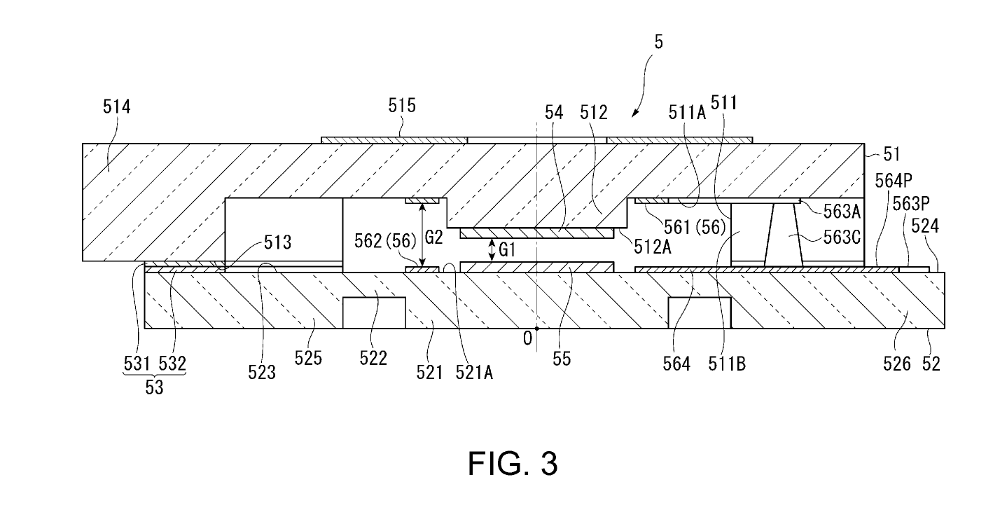

FIG. 2 is a plan view illustrating a schematic configuration of a wavelength variable interference filter. FIG. 3 is an arrow cross-sectional view illustrating the wavelength variable interference filter when taken along line III-III of FIG. 2.

The wavelength variable interference filter 5 is a wavelength variable-type Fabry-Perot etalon. The wavelength variable interference filter 5 is, for example, a rectangular plate-like optical member, and includes a fixed substrate 51 which is formed to have a thickness of, for example, approximately 500 μm and a movable substrate 52 which is formed to have a thickness of, for example, approximately 200 μm. The fixed substrate 51 and the movable substrate 52 are formed of, for example, various types of glass such as soda glass, crystalline glass, silica glass, lead glass, potassium glass, borosilicate glass, and alkali-free glass, a quartz crystal, or the like. The fixed substrate 51 and the movable substrate 52 are integrally formed by a first bonding portion 513 of the fixed substrate 51 and a second bonding portion 523 of the movable substrate 52 being bonded to each other by a bonding film 53 (first bonding film 531 and second bonding film 532) which is constituted by, for example, a siloxane-based plasma polymerized film or the like.

The fixed substrate 51 is provided with a fixed reflective film 54, and the movable substrate 52 is provided with a movable reflective film 55. The fixed reflective film 54 and the movable reflective film 55 are disposed so as to face each other with a gap G1 interposed therebetween. The wavelength variable interference filter 5 is provided with an electrostatic actuator 56 used for adjusting (changing) the size of the gap G1.

In addition, in planar view as shown in FIG. 2 when the wavelength variable interference filter 5 is seen from in the thickness direction of the fixed substrate 51 (movable substrate 52) (hereinafter, referred to as the planar view of the filter), a plane center point O of the fixed substrate 51 and the movable substrate 52 is assumed to be coincident with a center point of the fixed reflective film 54 and the movable reflective film 55, and coincident with a center point of a movable portion 521 described later.

In the planar view of the filter, one side (for example, side C1-C2 in FIG. 2) of the sides of the movable substrate 52 protrudes further outside than the fixed substrate 51. The protruding portion of the movable substrate 52 is an electronic component portion 526 which is not bonded to the fixed substrate 51. A surface of the electronic component portion 526 of the movable substrate 52 which is exposed when the wavelength variable interference filter 5 is seen from the fixed substrate 51 side is an electronic component surface 524, and is provided with electrode pads 563P and 564P (equivalent to connection terminals according to the invention) described later.

### Configuration of Fixed Substrate

An electrode arrangement groove 511 and a reflective film installing portion 512 are formed on the fixed substrate 51 by etching.

In the planar view of the filter, the electrode arrangement groove 511 is formed in an annular shape centering on the plane center point O of the fixed substrate 51. In the planar view of the filter, the reflective film installing portion 512 is formed so as to protrude from the central portion of the electrode arrangement groove 511 to the movable substrate 52 side. The groove bottom of the electrode arrangement groove 511 serves as an electrode installation surface 511A on which a fixed electrode 561 is disposed. In addition, the protruding apical surface of the reflective film installing portion 512 serves as a reflective film installation surface 512A.

In addition, the fixed substrate 51 is provided with an electrode extraction groove 511B extending from the electrode arrangement groove 511 toward the vertex of the fixed substrate 51 on the point C1 side of its outer circumferential edge.

The fixed electrode 561 constituting the electrostatic actuator 56 is provided on the electrode installation surface 511A of the electrode arrangement groove 511. More specifically, the fixed electrode 561 is provided on a region facing the movable electrode 562 of the movable portion 521, described later, in the electrode installing surface 511A. In addition, an insulating film for securing insulating properties between the fixed electrode 561 and the movable electrode 562 may be laminated on the fixed electrode 561.

The fixed substrate 51 is provided with a fixed extraction electrode 563A extending from the outer circumferential edge of the fixed electrode 561 in the direction of the point C1. The extending apical portion of the fixed extraction electrode 563A is electrically connected to a fixed connection electrode 563B provided on the movable substrate 52 side through a bump electrode 563C. The fixed connection electrode 563B extends to the electronic component surface 524 through the electrode extraction groove 511B, and constitutes the fixed electrode pad 563P which is equivalent to the connection terminal according to the invention in the electronic component surface 524. The fixed electrode pad 563P is connected to an inside terminal portion 624, described later, which is provided inside the housing 610.

Meanwhile, in the embodiment, the configuration is shown in which one fixed electrode 561 is provided on the electrode installing surface 511A, but a configuration (double electrode configuration) or the like may be formed, for example, in which two electrodes having a concentric circle centering on the plane center point O are provided.

As described above, the reflective film installing portion 512 is formed coaxially with the electrode arrangement groove 511 and in a substantially cylindrical shape having a diameter smaller than the electrode arrangement groove 511, and includes the reflective film installation surface 512A facing the movable substrate 52 of the reflective film installing portion 512.

As shown in FIG. 3, the fixed reflective film 54 is installed on the reflective film installing portion 512. As the fixed reflective film 54, for example, a metal film such as Ag, an alloy film such as an Ag alloy can be used. In addition, for example, a dielectric multilayer film in which a high refractive layer is formed of TiO₂ and a low refractive layer is formed of SiO₂ may be used. Further, a reflective film in which a metal film (or alloy film) is laminated on a dielectric multilayer film, a reflective film in which a dielectric multilayer film is laminated on a metal film (or an alloy film), a reflective film in which a single-layer refractive layer (such as TiO₂ or SiO₂) and a metal film (or an alloy film) are laminated, or the like may be used.

In addition, an anti-reflective film 515 is provided at a position corresponding to the fixed reflective film 54, on the light incidence plane (surface on which the fixed reflective film 54 is not provided) of the fixed substrate 51. Since the anti-reflective film 515 can be formed by alternately laminating a low refractive index film and a high refractive index film, the reflectance of visible light from the surface of the fixed substrate 51 is reduced, and the transmittance thereof is increased.

A surface on which the electrode arrangement groove 511, the reflective film installing portion 512, and the electrode extraction groove 511B are not formed by etching, in the surface of the fixed substrate 51 which faces the movable substrate 52, constitutes the first bonding portion 513. The first bonding portion 513 is provided with the first bonding film 531, and the first bonding film 531 is bonded to the second bonding film 532 provided on the movable substrate 52. Therefore, as described above, the fixed substrate 51 and the movable substrate 52 are bonded to each other. As shown in FIG. 3, in the planar view of the filter, the bonded fixed substrate 51 includes a protruding portion 514 protruding further outside than the movable substrate 52, on one side of the movable substrate 52 which is located on the opposite side to the electronic component portion 526. The protruding portion 514 is a portion which does not overlap the movable substrate 52 in the planar view of the filter.

### Configuration of Movable Substrate

In the planar view of the filter as shown in FIG. 2, the movable substrate 52 includes the circle-shaped movable portion 521 centering on the plane center point O, a holding portion 522, coaxial with the movable portion 521, which holds the movable portion 521, and a substrate outer circumferential portion 525 provided outside the holding portion 522.

In addition, as described above, the movable substrate 52 includes the electronic component portion 526, equivalent to the protruding portion according to the invention, which protrudes further outside the fixed substrate 51 on the side C1-C2 side, as shown in FIG. 2.

The movable portion 521 is formed to have a thickness larger than the holding portion 522, and is formed to have the same size as the thickness of the movable substrate 52, for example, in the present embodiment. In the planar view of the filter, the movable portion 521 is formed to have a diameter larger than at least the diameter of the outer circumferential edge of the reflective film installation surface 512A. The movable portion 521 is provided with the movable electrode 562 and the movable reflective film 55.

Meanwhile, similarly to the fixed substrate 51, an anti-reflective film may be formed on the surface of the movable portion 521 on the opposite side to the fixed substrate 51. Such an anti-reflective film can be formed by alternately laminating a low refractive index film and a high refractive index film, thereby allowing the reflectance of visible light from the surface of the movable substrate 52 to be reduced, and allowing the transmittance thereof to be increased.

The movable electrode 562 faces the fixed electrode 561 with a gap G2 interposed therebetween, and is formed in an annular shape having the same shape as that of the fixed electrode 561. The movable electrode 562 constitutes the electrostatic actuator 56 together with the fixed electrode 561. In addition, the movable substrate 52 includes a movable extraction electrode 564 which extends from the outer circumferential edge of the movable electrode 562 toward the electronic component surface 524 and reaches the electronic component surface 524. The extending apical portion of the movable extraction electrode 564 constitutes the movable electrode pad 564P which is equivalent to the connection terminal according to the invention in the electronic component surface 524. The movable electrode pad 564P is connected to the inside terminal portion 624, described later, which is provided in a pedestal portion 621.

On the central portion of a movable surface 521A of the movable portion 521, the movable reflective film 55 is provided facing the fixed reflective film 54 with the gap G1 interposed therebetween. As the movable reflective film 55, a reflective film having the same configuration as that of the above-mentioned fixed reflective film 54 is used.

Meanwhile, in the present embodiment, as described above, an example in which the size of the gap G2 is larger than that of the gap G1 is illustrated, but there is no limitation thereto. For example, when infrared rays or far-infrared rays are used as light to be measured, or the like, a configuration may be formed in which the size of the gap G1 becomes larger than the size of the gap G2 depending on the wavelength region of the light to be measured.

The holding portion 522 is a diaphragm that surrounds the periphery of the movable portion 521, and is formed to have a thickness smaller than the movable portion 521. Such a holding portion 522 is more likely to be bent than the movable portion 521, and thus can cause the movable portion 521 to be displaced to the fixed substrate 51 side due to slight electrostatic attractive force. At this time, the movable portion 521 has a thickness larger than the holding portion 522, and has a rigidity larger than that. Therefore, even when the holding portion 522 is pulled to the fixed substrate 51 side due to electrostatic attractive force, a change in the shape of the movable portion 521 is not caused. Therefore, the movable reflective film 55 provided on the movable portion 521 is not bent, and the fixed reflective film 54 and movable reflective film 55 can always be maintained to be in a parallel state.

Meanwhile, in the embodiment, the diaphragm-shaped holding portion 522 is illustrated by way of example, but without being limited thereto, for example, beam-shaped holding portions which are disposed at equiangular intervals centering on the plane center point O may be provided.

As described above, the substrate outer circumferential portion 525 is provided outside the holding portion 522 in the planar view of the filter. The surface of the substrate outer circumferential portion 525 facing the fixed substrate 51 includes the second bonding portion 523 facing the first bonding portion 513. The second bonding portion 523 is provided with the second bonding film 532, and the second bonding film 532 is bonded to the first bonding film 531 as described above. Thereby, the fixed substrate 51 and the movable substrate 52 are bonded to each other.

### Configuration of Housing

As shown in FIG. 1, the housing 610 includes a base 620 and a lid 630, and stores the wavelength variable interference filter 5 therein.

The base 620 includes the pedestal portion 621 and a sidewall portion 625.

The pedestal portion 621 is a plate-like portion having a rectangular contour in the planar view of the filter. The wavelength variable interference filter 5 is placed on a base inside surface 621A of the pedestal portion 621 facing the lid 630. The pedestal portion 621 is configured such that an opening of a light emission hole 622 penetrating therethrough in a thickness direction is formed in the central portion thereof. A glass window 623 on the emission side is bonded to the light emission hole 622.

In addition, as shown in FIG. 2, one corner of the base inside surface 621A is provided with the inside terminal portion 624 (equivalent to the terminal on the housing side according to the invention) which is connected to each of the electrode pads 563P and 564P of the wavelength variable interference filter 5. The inside terminal portion 624 and each of the electrode pads 563P and 564P are connected to each other using a wire 612 such as Au, for example, by wire bonding. Meanwhile, in the present embodiment, the wire bonding is illustrated by example, but, for example, an FPC (Flexible Printed Circuit) or the like may be used.

In addition, the pedestal portion 621 has a through-hole, not shown, formed at a position where the inside terminal portion 624 is provided. The inside terminal portion 624 is connected to an outside terminal portion, not shown, provided on the base outside surface 621B (surface on the opposite side to the base inside surface 621A) of the pedestal portion 621 through this through-hole.

The sidewall portion 625 stands up from the edge portion of the rectangular pedestal portion 621, and covers the periphery of the wavelength variable interference filter 5 placed on the base inside surface 621A. The surface (hereinafter, also referred to as an end face 625A) of the sidewall portion 625 facing the lid 630 is formed on a flat surface parallel to the base inside surface 621A.

The base 620 includes a fixing portion 626 at a position corresponding to one vertex (for example, in the present embodiment, vertex C2 of the movable substrate 52 in the electronic component portion 526) of the wavelength variable interference filter 5. The fixing portion 626 includes a pedestal fixing surface 627 (equivalent to a first surface according to the invention) facing the movable substrate 52, a groove portion 628 that surrounds the pedestal fixing surface 627 together with the sidewall portion 625, and a sidewall fixing surface 629 (equivalent to a second surface according to the invention) which is a portion of the sidewall portion 625.

In the pedestal portion 621, the pedestal fixing surface 627 faces a portion (corner) of the vicinity of the vertex C2 in a surface 52A (hereinafter, also referred to as a substrate surface 52A) of the movable substrate 52 on the opposite side to the fixed substrate 51.

The groove portion 628 is provided so as to surround the outer circumference of the pedestal fixing surface 627, and the groove lateral side on the pedestal fixing surface 627 side is continuous with the pedestal fixing surface 627 and serves as an intersection surface 628A (equivalent to a third surface according to the invention) intersecting the pedestal fixing surface 627. The width of the groove portion 628 in the planar view of the filter is such a size that a bonding member 7, described later, does not wet and spread onto the surface of the pedestal portion 621 beyond the groove portion 628 due to surface tension when the wavelength variable interference filter 5 and the base 620 are fixed to each other by the bonding member 7. Specifically, the above size is appropriately set depending on the viscosity or amount of the bonding member 7, a size between the fixing portion 626 and the movable substrate 52, and the like. In addition, FIG. 1 shows a case where the intersection surface 628A is at right angles to the pedestal fixing surface 627 as an example, but there is no limitation to a case where the intersection surface 628A and the pedestal fixing surface 627 are at right angles to each other. That is, an angle from the intersection surface 628A to the pedestal fixing surface 627 may be such an angle that the bonding member 7 does not wet and spread from the pedestal fixing surface 627 to the intersection surface 628A, depending on the viscosity or amount of the bonding member 7, a size between the fixing portion 626 and the movable substrate 52, and the like, and is preferably an angle larger than 270 degrees in a case of the above-mentioned right angles. The angle is set to be equal to or greater than 270 degrees, and thus it is possible to prevent the bonding member 7 from wetting and spreading from the pedestal fixing surface 627 to the intersection surface 628A more reliably.

The sidewall fixing surface 629 is a portion of the sidewall portion 625, and is continuous with the pedestal fixing surface 627. In the present embodiment, the fixing portion 626 is configured to be provided at the corner of the pedestal portion 621, and the sidewall fixing surface 629 has surfaces that respectively face lateral sides 527 and 528 of the wavelength variable interference filter 5.

In such a fixing portion 626, a portion of the outer circumference of the pedestal fixing surface 627 is continuous with the sidewall fixing surface 629, and the remaining portion is continuous with the intersection surface 628A of the groove portion 628.

Here, a size between the sidewall fixing surface 629 and the movable substrate 52 (lateral side of the movable substrate 52 in the electronic component portion 526) is set to L1, a size between a groove bottom 628B of the groove portion 628 and the surface 52A of the movable substrate 52 is set to L2, and a size between the pedestal fixing surface 627 and the surface of the movable substrate 52 on the opposite side to the fixed substrate 51 is set to L3. In the present embodiment, each of the sizes L1, L2, and L3 has a relation of L3<L1<L2 established.

In the planar view of the filter, the lid 630 has the same rectangular contour as that of the pedestal portion 621, and is formed of glass capable of transmitting light. The lid 630 is bonded to the end face 625A in a state where the wavelength variable interference filter 5 is disposed on the base inside surface 621A. A space surrounded by an inner surface 625B of the sidewall portion 625, the base inside surface 621A, and the lid 630 is an internal space 611 of the housing 610, and the lid 630 is bonded and sealed.

In the optical filter device 600 configured in this manner, light incident from the lid 630 side is incident on the wavelength variable interference filter 5. The light spectroscopically dispersed by the wavelength variable interference filter 5 is emitted from the light emission hole 622.

### Configuration of Bonding Member

As shown in FIGS. 1 and 2, the wavelength variable interference filter 5 is fixed to the housing 610 by the bonding member 7.

Specifically, the bonding member 7 is formed of, for example, an epoxy-based or silicon-based adhesive. In the fixing portion 626, the bonding member 7 is provided through the pedestal fixing surface 627 and the sidewall fixing surface 629, and comes into contact with a portion (corner on the vertex C2 side) of the surface 52A of the movable substrate 52, a portion facing the pedestal fixing surface 627, and two continuous lateral sides 527 and 528 of the movable substrate 52.

### Manufacturing of Optical Filter Device

First, the bonding member 7 is applied to the vicinity of the point C2 between the lateral sides 527 and 528 of the wavelength variable interference filter 5 which is created in advance. The lateral sides 527 and 528 are brought close to the inner surface 625B of the sidewall portion 625 in the base 620 while the movable substrate 52 is brought into contact with the base inside surface 621A, and the bonding member 7 is cured in the state. Meanwhile, as the bonding member 7, for example, a thermosetting resin is used. The thermosetting resin increases in flowability by heating, and is cured with the elapse of time.

Specifically, as shown in FIGS. 1 and 2, the lateral sides 527 and 528 of the wavelength variable interference filter 5 are brought close to the inner surface 625B of the base 620 so that the size L1 which is a distance between the lateral sides 527 and 528 of the wavelength variable interference filter 5 and the sidewall fixing surface 629 of the base 620 becomes smaller than the size L2 which is a distance between the groove bottom 628B of the base 620 and the surface 52A of the movable substrate 52. In this manner, when the wavelength variable interference filter 5 is disposed in the base 620, the bonding member 7 having flowability wets and spreads between the lateral sides 527 and 528 and the sidewall fixing surface 629, and between the surface 52A of the movable substrate 52 and the pedestal fixing surface 627.

In this case, since the size L3 is smaller than the size L2, an adhesive wets and spreads between the surface 52A of the movable substrate 52 and the pedestal fixing surface 627 having a small gap size therebetween, due to a capillary phenomenon. Thereafter, since the size L1 is smaller than the size L2, the bonding member 7 wets and spreads between the lateral sides 527 and 528 and the sidewall fixing surface 629 having a small gap size therebetween, due to a capillary phenomenon, and does not wet and spread to the groove portion 628 side having a large gap size.

The lateral sides 527 and 528 and the sidewall fixing surface 629 are bonded to each other by the bonding member 7 formed by the curing of an adhesive, and the surface 52A of the movable substrate 52 and the pedestal fixing surface 627 are bonded to each other. In this manner, the wavelength variable interference filter 5 is fixed to the base 620 by the bonding member 7.

Thereafter, each of the electrode pads 563P and 564P of the wavelength variable interference filter 5 and the inside terminal portion 624 of the base 620 are connected to each other by the wire 612 through wire bonding. Specifically, a wire is inserted into a capillary, and a ball (FAB; Free Air Ball) is formed on the apical end of the wire 612. The ball is brought into contact with the fixed electrode pad 563P by moving the capillary in this state, and a bond is formed. The wire is also connected to the inside terminal portion 624 by moving the capillary, and then the wire is cut off.

Meanwhile, as wire bonding, an example in which connection is performed using ball bonding has been described, but wedge bonding or the like may be used. In addition, for example, an FPC can be used without being limited to the connection using the wire bonding, and bonding using an Ag paste, an ACF (Anisotropic Conductive Film), an ACP (Anisotropic Conductive Paste), or the like may be performed.

Thereafter, the base 620 and lid 630 are bonded to each other. The bonding of the base 620 to the lid 630 is performed, for example, using low-melting-point glass under an environment set to a vacuum atmosphere by a vacuum chamber device or the like.

According to the above, the optical filter device 600 is manufactured.

### Operations and Effects of First Embodiment

In the present embodiment, the housing 610 includes the fixing portion 626 having the sidewall fixing surface 629 facing the lateral sides 527 and 528 of the movable substrate 52, the pedestal fixing surface 627 facing the surface 52A of the movable substrate 52, and the groove portion 628 that surrounds the pedestal fixing surface 627 in the pedestal portion 621. The groove bottom 628B of the groove portion 628 is further away from the movable substrate 52 than the pedestal fixing surface 627 in the thickness direction of the substrate, and surrounds the periphery of the pedestal fixing surface 627 together with the sidewall fixing surface 629 in the planar view of the filter. The bonding member 7 is provided between the lateral sides 527 and 528 of the movable substrate 52 and the sidewall fixing surface 629, and between the surface 52A of the movable substrate 52 and the pedestal fixing surface 627.

In such a configuration, even when an adhesive having flowability before curing is used as the bonding member 7, the wetting and spreading of the adhesive in the surface 52A of the movable substrate 52 can be regulated within the pedestal fixing surface 627. Thereby, it is possible to prevent the movable substrate 52 from bending due to the contraction stress, difference in thermal expansion coefficient, or the like of the bonding member 7.

On the other hand, even when the bonding member 7 between the lateral sides 527 and 528 of the movable substrate 52 and the sidewall fixing surface 629 is cured and contracted, or receives stress due to a difference in thermal expansion coefficient, the influence of stress on the movable substrate 52 is reduced. That is, the movable substrate 52 is a plate-like member, and has a size in a plane direction sufficiently larger than the thickness thereof and a rigidity in a plane direction larger than a rigidity in a thickness direction. Therefore, even when the bonding member 7 comes into contact with the lateral sides 527 and 528 of the movable substrate 52, it is possible to prevent the movable substrate 52 from bending.

In the present embodiment, as stated above, the bonding member 7 is provided extending between the pedestal fixing surface 627 and the substrate surface 52A, and between the sidewall fixing surface 629 and the lateral sides 527 and 528 of the movable substrate 52. Therefore, for example, as compared to a case where the bonding member 7 is provided only between the pedestal fixing surface 627 and the substrate surface 52A, or a case where the bonding member 7 is provided only between the sidewall fixing surface 629 and the lateral sides 527 and 528 of the movable substrate 52, it is possible to intensify a bonding strength, and to obtain a fixing force capable of preventing the wavelength variable interference filter 5 from falling off due to a vibration or the like.

In the present embodiment, the groove portion 628 is provided in the vicinity of the pedestal fixing surface 627 of the pedestal portion 621. In such a configuration, for example, as compared to a case where a through-hole is formed in the vicinity of the pedestal fixing surface 627 to constitute the intersection surface 628A continuous with the pedestal fixing surface 627, it is possible to increase the airtightness of the internal space 611 within the housing 610. In addition, when the housing 610 is sealed, it is possible to reduce the number of components without separately providing a member that seals the above through-hole.

In addition, since the distance (L2) between the lateral sides 527 and 528 of the movable substrate 52 and the sidewall fixing surface 629 is smaller than the distance (L1) between the movable substrate 52 and the groove bottom 628B of the groove portion 628, the bonding member 7 has a tendency to wet and spread between the lateral sides 527 and 528 of the movable substrate 52 and the sidewall fixing surface 629 due to a capillary phenomenon. Therefore, it is possible to more reliably prevent a disadvantage of the bonding member 7 wetting and spreading beyond the groove portion 628, to other than a region facing the pedestal fixing surface 627 on the surface 52A of the movable substrate 52.

In addition, the bonding member 7 is provided extending over two lateral sides 527 and 528 which are continuous with each other and are not flush with each other. According to this, since the movable substrate 52 is fixed to the housing 610 on each of the two lateral sides 527 and 528, it is possible to increase the fixing force of the movable substrate 52 with respect to the housing 610, and to more reliably fix the wavelength variable interference filter 5 to the housing 610.

In addition, the wavelength variable interference filter 5 is provided with chief members, influencing the spectral accuracy of the wavelength variable interference filter 5, such as each of the reflective films 54 and 55 or the movable portion 521 and the holding portion 522 constituting an electrostatic actuator, centering on the plane center point O.

The bonding member 7 is provided at a corner intersecting the lateral sides 527 and 528. Since this corner is away from the center position (plane center point O) of the movable substrate 52 in the planar view of the filter, it is possible to suppress the transmission of stress of the bonding member 7 to the above chief members provided in the vicinity of the plane center point O, and to suppress a deterioration in spectral accuracy more effectively.

Here, when both of a pair of substrates 51 and 52 are fixed to the inner surface 625B of the housing 610 by the bonding member 7, stress from the bonding member 7 is applied in a direction in which the pair of substrates 51 and 52 are brought close to each other or kept away from each other, and thus there is a concern that the pair of substrates 51 and 52 may not be able to be maintained in parallel to each other, or the size of the gap G1 between the reflective films may be fluctuated.

On the other hand, in the wavelength variable interference filter 5, the movable substrate 52 includes the electronic component portion 526 which does not overlap the fixed substrate 51 in the planar view of the filter. The lateral sides 527 and 528 of the electronic component portion 526 and the sidewall fixing surface 629 are fixed to each other by the bonding member 7. In addition, the substrate surface 52A of the electronic component portion 526 located on the opposite side to the electronic component surface 524, and the pedestal fixing surface 627 are fixed to each other by the bonding member 7.

In such a configuration, since the bonding member 7 is provided so that only the movable substrate 52 of the pair of substrates 51 and 52 is fixed to the housing 610, it is possible to maintain the parallel between the pair of substrates 51 and 52, and to suppress a fluctuation in the size of the gap G1 between the reflective films. Therefore, it is possible to suppress a deterioration in the spectral accuracy of the wavelength variable interference filter 5 due to the inability of the parallel between the substrates 51 and 52 to be maintained or a fluctuation in the size of the gap G1, and to maintain spectral accuracy.

Further, in the wavelength variable interference filter 5, in the planar view of the filter, the pedestal fixing surface 627 is located at a position overlapping the electronic component portion 526 without overlapping the fixed substrate 51, and the electronic component portion 526, and the pedestal fixing surface 627 and the sidewall fixing surface 629 are fixed to each other by the bonding member 7.

Thereby, it is possible to provide the bonding member 7 at a position of the movable substrate 52 which does not face the fixed substrate 51, and to more reliably fix only the movable substrate 52 to the housing 610 using the bonding member 7.

That is, since the bonding member 7 comes into contact with other than a region which is bonded by the bonding film 53 of the fixed substrate 51 and the movable substrate 52, contraction stress during the curing of the bonding member 7 or stress due to a difference in thermal expansion coefficient is not likely to be transmitted to the fixed substrate 51 side, and thus it is possible to prevent the fixed substrate 51 from bending.

In addition, the electronic component portion 526 provided with the bonding member 7 has each of the electrode pads 563P and 564P provided on the electronic component surface 524, and the pedestal fixing surface 627 and the bonding member are disposed at a position overlapping each of the electrode pads 563P and 564P in planar view. Each of the electrode pads 563P and 564P is connected to the inside terminal portion 624.

In such a configuration, the electronic component portion 526 is fixed to the housing 610 by the bonding member 7. Therefore, even when an impact is applied to the optical filter device 600, or the optical filter device 600 vibrates due to the driving of the optical filter device 600, it is possible to suppress the vibration of the electronic component portion 526. Therefore, it is possible to prevent a disadvantage such as the disconnection of a wiring between each of the electrode pads 563P and 564P and the inside terminal portion 624.

### Second Embodiment

Next, a second embodiment of the invention will be described with reference to the accompanying drawings.

In the present embodiment, in the base 620, a stepped portion is provided at a position overlapping the protruding portion 514 of the fixed substrate 51 in the planar view of the filter, and the fixed substrate 51 is fixed to the housing 610.

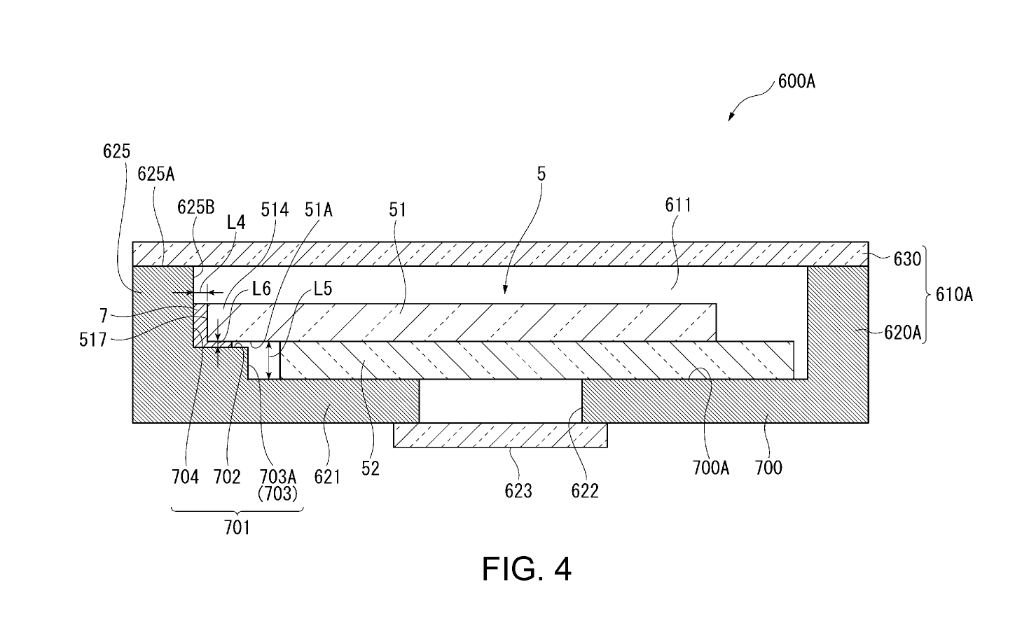

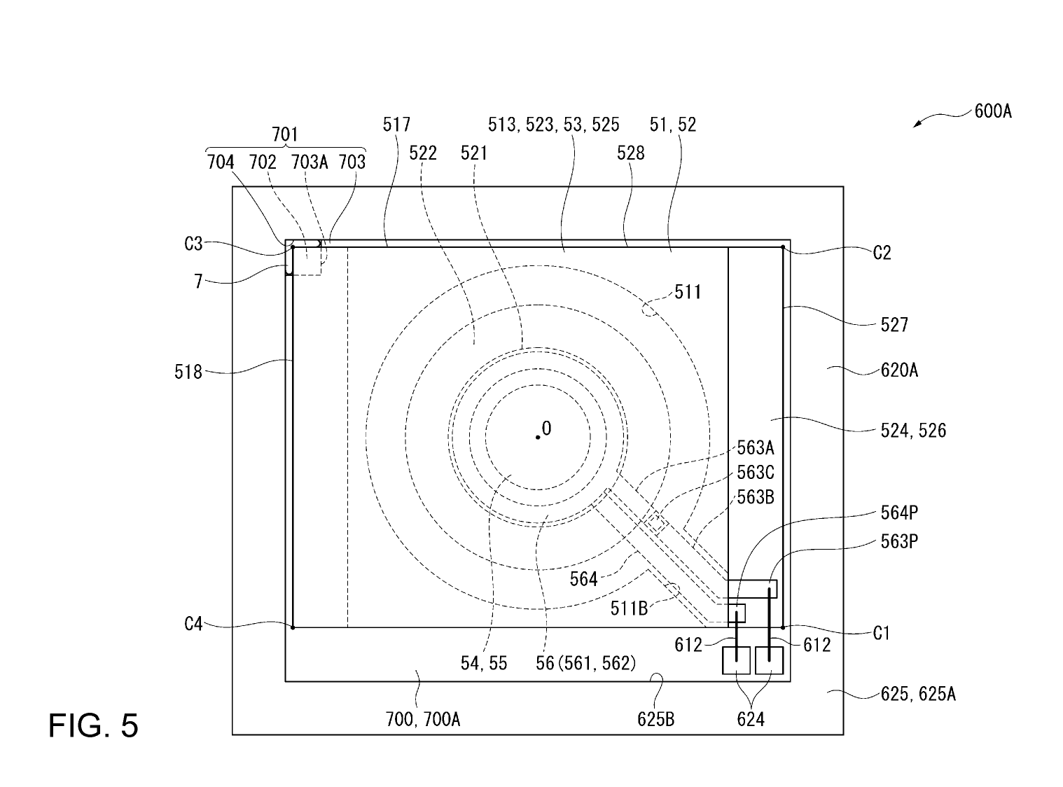

FIG. 4 is a cross-sectional view illustrating a schematic configuration of an optical filter device 600A according to the second embodiment of the invention, and FIG. 5 is a plan view illustrating a schematic configuration of the optical filter device 600A. Meanwhile, in FIG. 5, the lid 630 is not shown. In addition, in the following description, components described previously are denoted by the same reference numerals and signs, and thus the description thereof will be omitted or simplified.

The optical filter device 600A includes a housing 610A, and the wavelength variable interference filter 5 which is stored inside the housing 610A.

### Configuration of Housing

As shown in FIGS. 4 and 5, the housing 610A includes a base 620A and the lid 630, and stores the wavelength variable interference filter 5 therein.

The base 620A includes a pedestal portion 700 and the sidewall portion 625.

In the planar view of the filter, the pedestal portion 700 is provided with a fixing portion 701 at a position corresponding to a vertex C3 in the protruding portion 514 of the fixed substrate 51. The fixing portion 701 is constituted by a pedestal fixing surface 702 provided on the pedestal portion 700, a groove portion 703 that surrounds a portion of the pedestal fixing surface 702, and a sidewall fixing surface 704. In the present embodiment, the protruding portion 514 of the fixed substrate 51 is fixed to the pedestal fixing surface 702, and the movable substrate is disposed within the groove portion 703.

In the pedestal portion 700, the pedestal fixing surface 702 faces a portion (corner) of the vicinity of the vertex C3 in a surface 51A (hereinafter, also referred to as a substrate surface 51A) of the fixed substrate 51 on the movable substrate 52 side.

The groove portion 703 is a groove provided so as to surround a portion which is not continuous with the sidewall fixing surface 704 in the outer circumference of the pedestal fixing surface 702. The groove lateral side on the pedestal fixing surface 702 side in the groove lateral side of the groove portion 703 is continuous with the pedestal fixing surface 702, and serves as an intersection surface 703A (equivalent to a third surface according to the invention) intersecting the pedestal fixing surface 702. In addition, the groove lateral side other than the intersection surface 703A in the groove lateral side of the groove portion 703 is a portion on the base inside surface 700A side based on the pedestal fixing surface 702, in the inner surface 625B of the sidewall portion 625. In addition, the groove bottom of the groove portion 703 is the base inside surface 700A, and the wavelength variable interference filter 5 is disposed in the groove portion 703.

The sidewall fixing surface 704 is a portion of the inner surface 625B of the sidewall portion 625, and is continuous with the pedestal fixing surface 702. Meanwhile, in the present embodiment, the sidewall fixing surface 704 also has surfaces facing lateral sides 517 and 518 of the wavelength variable interference filter 5, respectively.

In such a fixing portion 701, a portion of the outer circumference of the pedestal fixing surface 702 is continuous with the sidewall fixing surface 704, and the remaining portion is continuous with of the intersection surface 703A of the groove portion 703.

Here, a size between the sidewall fixing surface 704 and the fixed substrate 51 (protruding portion 514) is set to L4, a size between the base inside surface 700A which is a groove bottom of the groove portion 703 and the substrate surface 51A of the fixed substrate 51 is set to L5, and a size between the pedestal fixing surface 702 and the substrate surface 51A of the fixed substrate 51 is set to L6. In the present embodiment, each of the sizes L4, L5, and L6 has a relation of L6<L4<L5 established.

### Configuration of Bonding Member

In the fixing portion 701, the bonding member 7 is provided through the pedestal fixing surface 702 and the sidewall fixing surface 704, and comes into contact with a portion of (corner on the vertex C3 side) of the substrate surface 51A of the fixed substrate 51, a portion facing the pedestal fixing surface 702, and two continuous lateral sides 517 and 518 of the fixed substrate 51.

### Manufacturing of Optical Filter Device

First, an adhesive for forming the bonding member 7 is applied to the vicinity of the point C3 between the lateral sides 517 and 518 of the wavelength variable interference filter 5 which is created in advance. The lateral sides 517 and 518 are brought close to the inner surface 625B of the sidewall portion 625 while the movable substrate 52 is bring into contact with the base inside surface 621A, and the adhesive is cured in the state.

Specifically, the lateral sides 517 and 518 of the wavelength variable interference filter 5 are brought close to the inner surface 625B so that the size L4 between the lateral sides 517 and 518 and the sidewall fixing surface 704 becomes smaller than the size L5 between the base inside surface 700A which is a groove bottom and the substrate surface 51A. In this manner, when the wavelength variable interference filter 5 is disposed in the groove portion 703 of the base 620A, the bonding member 7 wets and spreads between the lateral sides 517 and 518 and the sidewall fixing surface 704, and between the substrate surface 51A of the fixed substrate 51 and the pedestal fixing surface 702.

In this case, since the size L6 is smaller than the size L5, the bonding member 7 wets and spreads between the substrate surface 51A of the fixed substrate 51 and the pedestal fixing surface 702, due to a capillary phenomenon. Thereafter, since the size L4 is smaller than the size L5, the bonding member 7 wets and spreads between the lateral sides 517 and 518 and the sidewall fixing surface 704, due to a capillary phenomenon, and does not wet and spread to the groove portion 703 side having a large gap size.

The lateral sides 517 and 518 and the sidewall fixing surface 704 are bonded to each other by the bonding member 7 formed by the curing of an adhesive, and the substrate surface 51A of the fixed substrate 51 and the pedestal fixing surface 702 are bonded to each other.

Hereinafter, similarly to the first embodiment, each of the electrode pads 563P and 564P of the wavelength variable interference filter 5 and the inside terminal portion 624 of the base 620A are connected to each other by the wire 612 through wire bonding. The base 620 and the lid 630 are bonded to each other.

According to the above, the optical filter device 600A is manufactured.

### Operations and Effects of Second Embodiment

In the present embodiment, in the wavelength variable interference filter 5, the movable substrate 52 includes the holding portion 522 that replaceably holds the movable portion 521 in a thickness direction. The bonding member 7 is provided to the fixed substrate 51 having a larger rigidity rather than the movable substrate 52, provided with the holding portion 522, of which the rigidity deteriorates, and thus it is possible to suppress the generation of bending in each of the substrates 51 and 52, and to suppress a deterioration in the spectral accuracy of the wavelength variable interference filter 5.

### Third Embodiment

Next, a third embodiment of the invention will be described with reference to the accompanying drawings.

In the third embodiment, a colorimetric sensor 3 which is an optical module having the optical filter device 600 of the above first embodiment built-in and a colorimeter 1 which is an electronic device having the optical filter device 600 built-in will be described.

### Schematic Configuration of Colorimeter

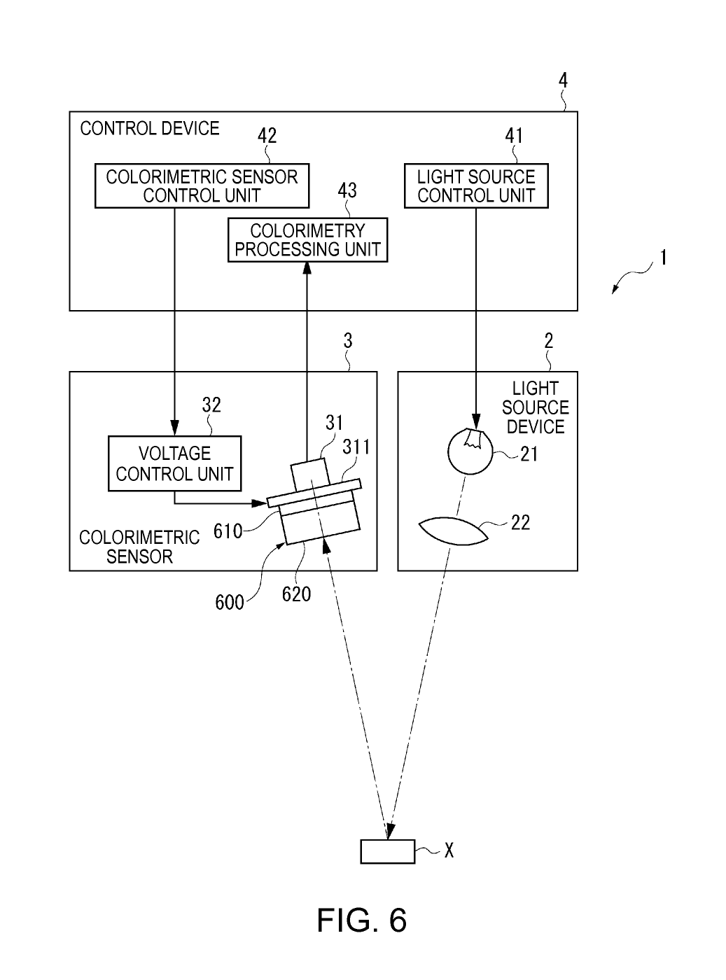

FIG. 6 is a block diagram illustrating a schematic configuration of the colorimeter 1.

The colorimeter 1 is an electronic device according to the invention. As shown in FIG. 6, the colorimeter 1 includes a light source device 2 that emits light to a test object X, a colorimetric sensor 3, and a control device 4 that controls the entire operation of the colorimeter 1. The colorimeter 1 receives light to be tested, which is emitted from the light source device 2 and reflected from the test object X, in the colorimetric sensor 3. The colorimeter 1 is a device that analyzes and measures the chromaticity of the light to be tested, that is, the color of the test object X, on the basis of a received detection signal which is output from the colorimetric sensor 3.

Configuration of Light Source Device

The light source device 2 includes a light source 21 and a plurality of lenses 22 (only one is shown in FIG. 6), and emits white light to the test object X. In addition, a collimator lens may be included in the plurality of lenses 22. In this case, the light source device 2 changes the white light emitted from the light source 21 to parallel light using the collimator lens, and emits the parallel light from a projection lens, not shown, toward the test object X. Meanwhile, in the present embodiment, the colorimeter 1 including the light source device 2 is illustrated, but when the test object X is, for example, a light-emitting member such as a liquid crystal panel, the light source device 2 may not be provided.

### Configuration of Colorimetric Sensor

The colorimetric sensor 3 constitutes an optical module according to the invention, and includes the optical filter device 600 of the above-mentioned first embodiment. As shown in FIG. 6, the colorimetric sensor 3 includes the optical filter device 600, a detection unit 31 that receives light passing through the optical filter device 600, and a voltage control unit 32 that changes the wavelength of transmitted light of the wavelength variable interference filter 5.

In addition, the colorimetric sensor 3 includes an incident optical lens, not shown, which guides reflected light (light to be tested) which is reflected from the test object X into the inside, at a position facing the wavelength variable interference filter 5. The colorimetric sensor 3 spectroscopically disperses light having a predetermined wavelength in the light to be tested which is incident from the incident optical lens using the wavelength variable interference filter 5 within the optical filter device 600, and receives the spectroscopically dispersed light in the detection unit 31.

The detection unit 31 is constituted by a plurality of photoelectric conversion elements, and generates an electrical signal according to the amount of light received. Here, the detection unit 31 is connected to the control device 4 through, for example, a circuit substrate 311, and outputs the generated electrical signal as a light receiving signal to the control device 4.

In addition, an outside terminal portion formed on the base outside surface 621B of the housing 610 is connected to the circuit substrate 311, and is connected to the voltage control unit 32 through a circuit formed in the circuit substrate 311.

In such a configuration, it is possible to integrally form the optical filter device 600 and the detection unit 31 with the circuit substrate 311 interposed therebetween, and to simplify the configuration of the colorimetric sensor 3.

The voltage control unit 32 is connected to an outside terminal portion of the optical filter device 600 through the circuit substrate 311. The voltage control unit 32 applies a predetermined step voltage between the fixed electrode pad 563P and the movable electrode pad 564P on the basis of a control signal which is input from the control device 4, and thus drives the electrostatic actuator 56. Thereby, the holding portion 522 bends due to the generation of an electrostatic attractive force in a gap between the electrodes, and thus the movable portion 521 is replaced to the fixed substrate 51 side, thereby allowing the gap G1 between reflective films to be set to have a desired size.

### Configuration of Control Device

The control device 4 controls the entire operation of the colorimeter 1.

As the control device 4, for example, a general-purpose personal computer, a portable information terminal, other special computers for colorimetry, or the like can be used.

As shown in FIG. 6, the control device 4 includes a light source control unit 41, a colorimetric sensor control unit 42, a colorimetry processing unit 43, and the like.

The light source control unit 41 is connected to the light source device 2. The light source control unit 41 outputs a predetermined control signal to the light source device 2, for example, on the basis of a user's setting input, and emits white light of predetermined brightness from the light source device 2.

The colorimetric sensor control unit 42 is connected to the colorimetric sensor 3. The colorimetric sensor control unit 42 sets the wavelength of light received by the colorimetric sensor 3, for example, on the basis of a user's setting input, and outputs a control signal for detecting the amount of received light of the wavelength to the colorimetric sensor 3. Thereby, the voltage control unit 32 of the colorimetric sensor 3 sets a voltage applied to the electrostatic actuator 56 so as to transmit only the wavelength of light desired by a user, on the basis of the control signal.

The colorimetry processing unit 43 analyzes the chromaticity of the test object X from the amount of light received which is detected by the detection unit 31.

### Operations and Effects of Third Embodiment

The colorimeter 1 of the present embodiment includes the optical filter device 600 as in the above-mentioned first embodiment. As described above, according to the optical filter device 600, it is possible to suppress the expansion of a fixed area due to an adhesive wetting and spreading between the movable substrate 52 and the base 620, and to adjust a desired size of the fixed area. Therefore, it is possible to obtain a desired fixing force while suppressing the bending of the substrate due to contraction stress of the adhesive, and to provide the colorimetric sensor 3 and the colorimeter 1 which have a desired performance and the high reliability of an impact or a vibration.

In addition, the optical filter device 600 has high airtightness of the internal space and is not subject to the infiltration of foreign substances such as water particles, and thus can prevent the optical characteristics of the wavelength variable interference filter 5 from being changed due to these foreign substances. Therefore, in the colorimetric sensor 3, it is also possible to detect light, having a target wavelength, extracted at a high resolution using the detection unit 31, and to detect the precise amount of light with respect to light having a desired target wavelength. Thereby, the colorimeter 1 can perform the precise color analysis of the test object X.

### Modification of Embodiment

Meanwhile, the invention is not limited to the above-mentioned embodiment, but changes, modifications and the like within the range capable of achieving the object of the invention are included in the invention.

For example, in each of the above-mentioned embodiments, a configuration is illustrated in which the fixing portion has the groove portion that covers the periphery of the pedestal fixing surface, but there is no limitation thereto. The fixing portion may be provided with a through-hole in the vicinity of the pedestal fixing surface. In this case, it is also possible to prevent the bonding member from wetting and spreading between the substrate facing the base inside surface of the wavelength variable interference filter 5 and the base inside surface, beyond the outer circumferential portion of the pedestal fixing surface in the planar view of the filter. Meanwhile, when the base is provided with a through-hole in this manner, a lid is bonded to the base due to atmospheric pressure, and then the inside of the housing is decompressed from the through-hole. Thereafter, the through-hole is blocked, thereby allowing the optical filter device to be manufactured.

In each of the above-mentioned embodiments, a configuration is illustrated in which, when any of the substrates 51 and 52 is fixed to the housing 610, the bonding member 7 is provided extending over two lateral sides intersecting each other, but the bonding member 7 may be provided on one lateral side without being limited thereto.

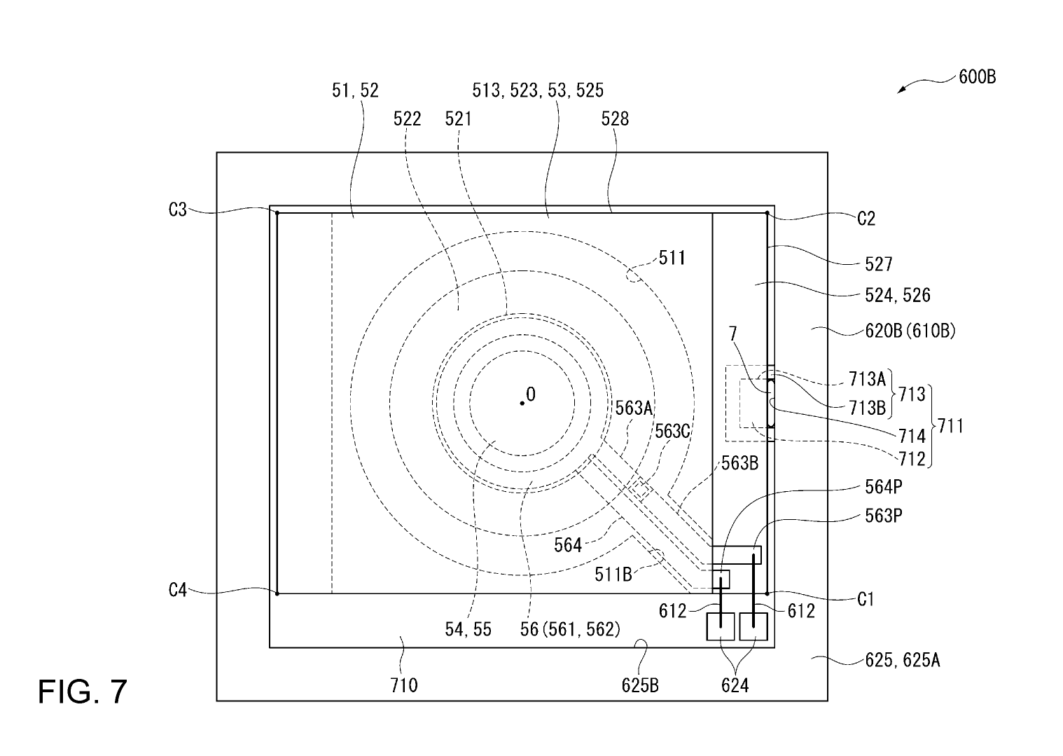

FIG. 7 is a plan view illustrating a modification example of the optical filter device. A housing 610B of an optical filter device 600B shown in FIG. 7 includes a base 620B and the lid 630 (see FIG. 1). The base 620B includes a pedestal portion 710 and the sidewall portion 625, and the pedestal portion 710 is provided with a fixing portion 711 along the side C1-C2 of the movable substrate 52.

In the planar view of the filter, the fixing portion 711 includes a pedestal fixing surface 712 provided at a position overlapping the side C1-C2 of the movable substrate 52, a groove portion 713, provided in the pedestal portion 621, which surrounds the pedestal fixing surface 712, and a sidewall fixing surface 714, continuous with the pedestal fixing surface 712, which is a portion of the sidewall portion 625. In addition, the groove portion 713 includes an intersection surface 713A continuous with the pedestal fixing surface 712, and a groove bottom 713B, continuous with the intersection surface 713A, which faces the surface 52A of the movable substrate 52.

The bonding member 7 is provided between the surface 52A of the movable substrate 52 and the pedestal fixing surface 712, and between the lateral side 527 and the sidewall fixing surface 714.

In the modification example, a size between the lateral side 527 and the sidewall fixing surface 714 is smaller than a size between the groove bottom 713B and the movable substrate 52. In addition, a size between the pedestal fixing surface 712 and the surface 52A of the movable substrate 52 is smaller than the size between the lateral side 527 and the sidewall fixing surface 714.

In the above-mentioned first embodiment, a configuration is illustrated in which the fixing portion 626 is provided at a position where the fixing portion does not interfere with each of the electrode pads 563P and 564P, but there is no limitation thereto. For example, in the planar view of the filter, the fixing portion may be provided so that the pedestal fixing surface (first surface) and the bonding member 7 are disposed at a position overlapping each of the electrode pads 563P and 564P. Thereby, even when a force to press the electronic component surface 524 in the thickness direction of the substrate is applied to the electronic component portion 526 at the time of connecting each of the electrode pads 563P and 564P and the inside terminal portion 624 through wire bonding or the like, the electronic component portion 526 can be supported from the opposite side to the electronic component surface 524 by the bonding member 7 and the pedestal fixing surface which are disposed on the opposite side to the electronic component surface 524. Thereby, it is possible to prevent the movable substrate 52 from inclining due to a pressing force when each of the electrode pads 563P and 564P and the inside terminal portion 624 are connected to each other.

In each of the above-mentioned embodiments, the housing includes the sidewall portion 625 capable of fixing the wavelength variable interference filter 5, but the invention is not limited thereto. For example, the housing does not include the sidewall portion capable of fixing the wavelength variable interference filter 5, but may be configured to include a support portion that supports the wavelength variable interference filter 5 instead thereof.

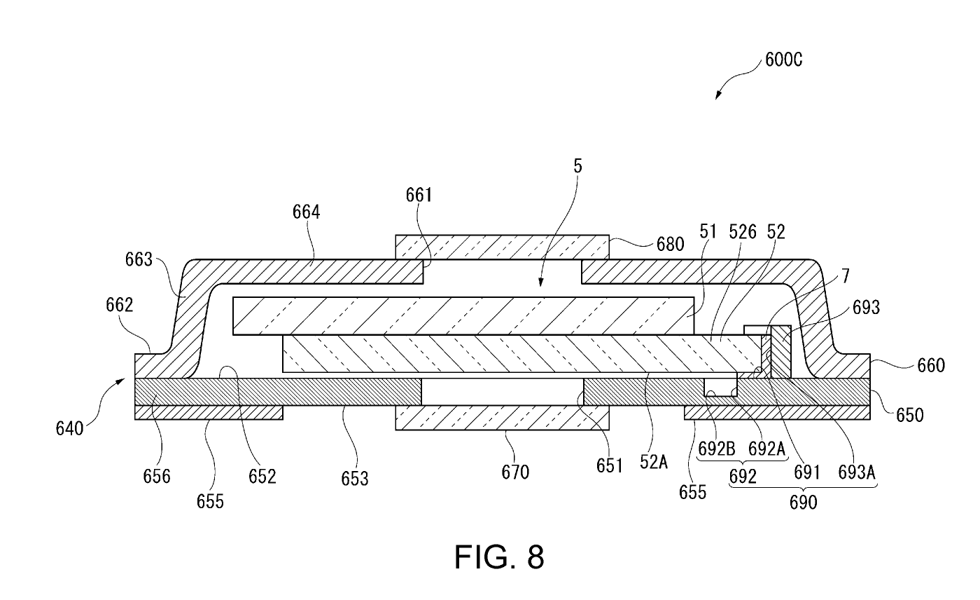

FIG. 8 is a cross-sectional view illustrating a modification example of the optical filter device.

As shown in FIG. 8, an optical filter device 600C includes a wavelength variable interference filter 5 and a housing 640 that stores the wavelength variable interference filter 5.

The housing 640 includes a base substrate 650, a lid 660, a glass substrate 670 on the base side, and a glass substrate 680 on the lid side.

The base substrate 650 has the movable substrate 52 of the wavelength variable interference filter 5 installed thereon. A light passing hole 651 is formed in the base substrate 650 in an open state, and the glass substrate 670 on the base side is bonded thereto so as to cover the light passing hole 651. An inside terminal portion, not shown, to which each of the electrode pads 563P and 564P of the wavelength variable interference filter 5 is connected is provided on a base inside surface 652 facing the lid 660 of the base substrate 650. Each inside terminal portion is connected to an outside terminal portion 655 provided on a base outside surface 653 of the base substrate 650. A base bonding portion 656 bonded to the lid 660 is provided on the outer circumferential portion of the base substrate 650.

The base substrate 650 includes a fixing portion 690 that fixes the wavelength variable interference filter 5. The fixing portion 690 includes a base fixing surface 691, provided on the base substrate 650, which is equivalent to a first surface according to the invention, a groove portion 692, provided in the base substrate 650, which surrounds a portion of the base fixing surface 691, and a support member 693 that comes into contact with the remaining portion of the base fixing surface 691.

The support member 693 has an L-shaped contour in the planar view of the filter, and protrudes in a direction away from the base substrate 650. The support member 693 includes a sidewall fixing surface 693A, facing each of the lateral sides 517 and 518 of the wavelength variable interference filter 5, which is equivalent to a second surface according to the invention.

In addition, the groove portion 692 includes an intersection surface 692A continuous with the base fixing surface 691, and a groove bottom 692B, continuous with the intersection surface 692A, which faces the surface 52A of the movable substrate 52.

The bonding member 7 is provided between the surface 52A of the movable substrate 52 and the base fixing surface 691, and between each of the lateral sides 527 and 528 and the sidewall fixing surface 693A.

In the modification example, a size between each of the lateral sides 527 and 528 and the sidewall fixing surface 693A is also smaller than a size between the groove bottom 692B and the movable substrate 52. In addition, a size between the base fixing surface 691 and the surface 52A of the movable substrate 52 is smaller than the size between each of the lateral sides 527 and 528 and the base fixing surface 691.

With such a configuration, even when the housing 640 is used in which the wavelength variable interference filter 5 having the base substrate 650 disposed thereon does not include a sidewall portion, the wavelength variable interference filter 5 can be fixed to the housing 640.

The lid 660 includes a lid bonding portion 662 bonded to the base bonding portion 656, a sidewall portion 663 standing up from the lid bonding portion 662, and a ceiling portion 664, continuous with the sidewall portion 663, which covers the wavelength variable interference filter 5. The lid 660 is bonded closely to the base substrate 650 by the lid bonding portion 662 and the base bonding portion 656 of the base substrate 650 being bonded to each other. A light passing hole 661 is formed in the ceiling portion 664 in an open state. The glass substrate 680 on the lid side is bonded thereto so as to cover the light passing hole 661.

In each of the above-mentioned embodiments, a configuration is illustrated in which any of the fixed substrate 51 and the movable substrate 52 are fixed to each other by the bonding member 7, but both the fixed substrate 51 and the movable substrate 52 may be fixed to each other by the bonding member 7 without being limited thereto. However, in this case, when a material having a difference in linear expansion coefficient which is greatly different from that of the fixed substrate 51 or the movable substrate 52 is used as the bonding member 7, or an adhesive having a compressive force in a thickness direction greater than the rigidity of the bonding film 53 is used as the bonding member, the inclination of the fixed substrate 51 and the movable substrate 52, or the fluctuation of the gap size is caused. Therefore, as in each of the embodiments mentioned above, it is preferable that the bonding member 7 be provided to any one of the fixed substrate 51 and the movable substrate 52.

In each of the above-mentioned embodiments, a configuration is illustrated in which the bonding member 7 is provided extending over two lateral sides in one corner of any of the substrates 51 and 52, but the bonding member 7 may be provided to a plurality of corners without being limited thereto. In addition, in each of the above-mentioned embodiments, a configuration is illustrated in which the bonding member 7 is provided to only one lateral side of the substrate, but the bonding member 7 may be provided at a plurality of places without being limited thereto.

In each of the above-mentioned embodiments, a configuration is illustrated in which the wavelength variable interference filter 5 is installed in the housing so that the movable substrate 52 serves as the pedestal portion side of the base, but there is no limitation thereto. For example, the wavelength variable interference filter 5 may be installed in the housing so that the fixed substrate 51 serves as the pedestal portion side.

Meanwhile, as in the embodiment, the movable substrate 52 is disposed in the pedestal portion 621, and thus the opening edge of the light emission hole 622 can be disposed at a position facing the holding portion 522 of the movable substrate 52. In this case, for example, even when a protrusion such as a burr occurs along the opening edge during the formation of the base 620, it is possible to escape the protrusion in an etching space of the holding portion 522, and to suppress the inclination of the movable substrate 52 or the like.

In each of the above-mentioned embodiments, a configuration is illustrated in which a voltage is applied to the fixed electrode 561 and the movable electrode 562 as the wavelength variable interference filter 5 to thereby change the size of the gap G1 between reflective films due to an electrostatic attractive force, there is no limitation thereto. For example, as the actuator having the gap G1 between reflective films changed, a dielectric actuator may be used in which a first inductive coil is disposed instead of the fixed electrode 561, and a second inductive coil or a permanent magnet is disposed instead of the movable electrode 562.

Further, a piezoelectric actuator may be used instead of the electrostatic actuator 56. In this case, for example, a lower electrode layer, a piezoelectric film, and an upper electrode layer are laminated on the holding portion 522, and a voltage applied between the lower electrode layer and the upper electrode layer is made available as an input value, thereby allowing the holding portion 522 to be bent by expanding and contracting the piezoelectric film.

In each of the above-mentioned embodiments, the wavelength variable interference filter 5 configured to be able to change the gap G1 between reflective films is illustrated, but an interference filter having a fixed size of the gap G1 between reflective films may be used without being limited thereto.

In addition, in each of the above-mentioned embodiments, a configuration is illustrated in which the wavelength variable interference filter 5 includes a pair of substrates 51 and 52 and a pair of reflective films 54 and 55 provided to each of the substrates 51 and 52, but there is no limitation thereto. For example, the movable substrate 52 may not be provided, and the fixed substrate 51 may be fixed to the housing 610. In this case, for example, a first reflective film, a gap spacer, and a second reflective film are laminated on one surface of the substrate (fixed substrate), and the first reflective film and the second reflective film face each other with a gap interposed therebetween. In such a configuration, a configuration constituted by one substrate is used, and a spectral element can be made thinner.

In addition, in each of the above-mentioned embodiments, the optical filter device is illustrated in which the wavelength variable interference filter or the interference filter is stored in the housing, but the invention is not limited thereto.

For example, the invention can also be suitably applied to a MEMS device having a MEMS element stored in the housing.

As the MEMS element, for example, an optical element such as a mirror device capable of precisely changing the reflection direction of light is illustrated. In such a configuration, it is also possible to prevent a substrate included in the optical element from bending, and to prevent stress from being applied to an optical member included in the optical element. Therefore, it is possible to prevent the optical characteristics of the optical element from being deteriorated.

Besides, as the MEMS element, various types of MEMS elements can be illustrated, such as a piezoelectric vibrating element (for example, quartz crystal vibrator, ceramic vibrator, or silicon vibrator), a pressure sensor element, an acceleration sensor element, and a gyro sensor element, which are stored in the housing for the purpose of performance improvement, degradation prevention, and the like.

In the piezoelectric vibrating element, the substrate is prevented from bending, and thus it is possible to prevent stress from being applied to the vibrator, and to prevent the characteristics of vibration from being changed. In the pressure sensor element, it is possible to prevent stress from being applied to a diaphragm, and to thereby prevent detection accuracy from being deteriorated due to the deformation of the diaphragm. In the acceleration sensor element and the gyro sensor element, similarly, it is possible to prevent stress from being applied to a detection unit provided on the substrate in order to detect acceleration and an angular velocity, and to prevent detection accuracy from being deteriorated.

In addition, although the colorimeter 1 is illustrated as the electronic device according to the invention in the third embodiment, the optical filter device, the optical module, and the electronic device according to the invention can be used in other various fields.

Hereinafter, a modification example of the electronic device using the optical filter device according to the invention will be described. Meanwhile, the electronic device illustrated below includes the above-mentioned optical filter device 600, and has the wavelength variable interference filter 5 fixed to the housing 610 by the bonding member 7.

The electronic device according to the invention can be used as, for example, a light-bases system for detecting the presence of a specific substance. As such a system, for example, a spectroscopic measurement system using a wavelength variable interference filter included in the optical filter device according to the invention is adopted, and a gas leak detector for a vehicle that detects a specific gas with a high degree of sensitivity, or a gas detector such as a photoacoustic rare gas detector for a breath test can be used.

An example of such a gas detector will be described below with reference to the accompanying drawings.

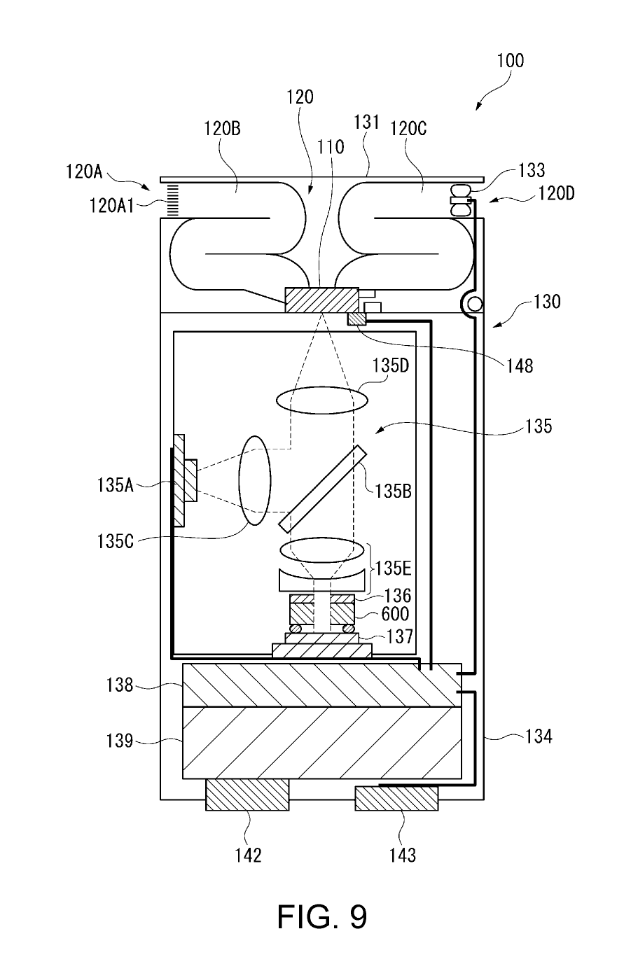

FIG. 9 is a schematic diagram illustrating an example of a gas detector including the wavelength variable interference filter.

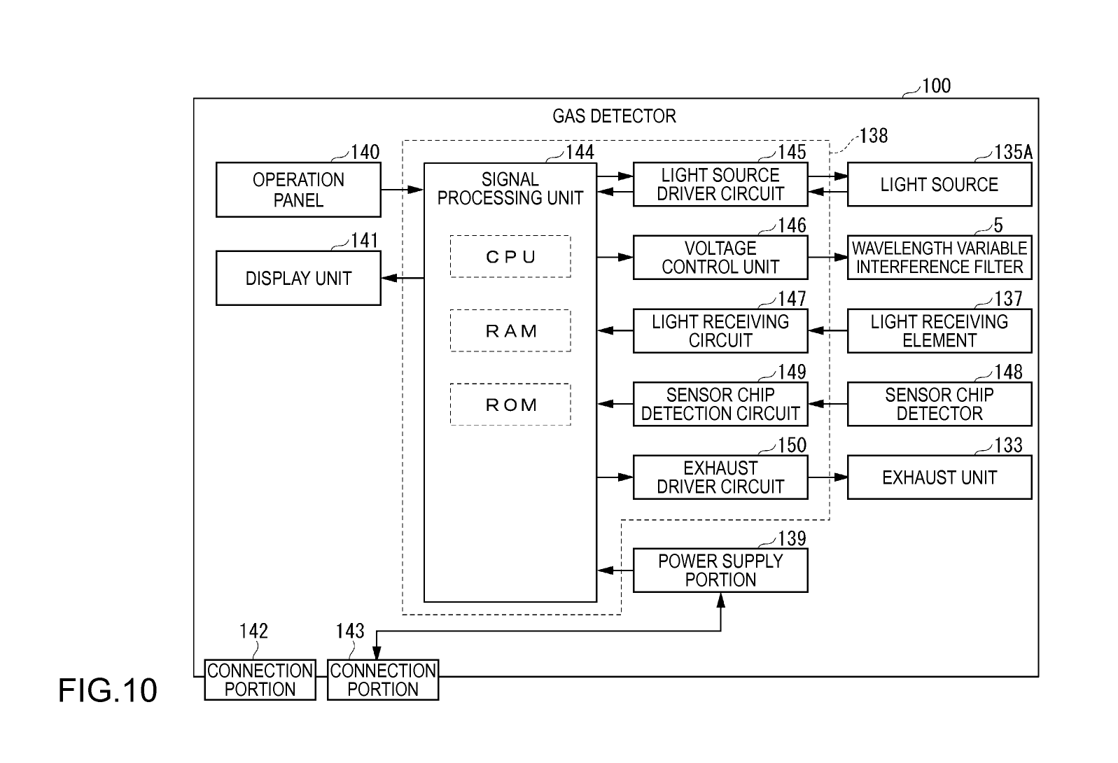

FIG. 10 is a block diagram illustrating a configuration of a control system of the gas detector in FIG. 9.

As shown in FIG. 9, the gas detector 100 includes a sensor chip 110, a flow channel 120 provided with a suction port 120A, a suction flow channel 120B, an exhaust flow channel 120C, and an exhaust port 120D, and a main body 130.

The main body 130 is constituted by a detector including a sensor cover 131 having an opening capable of attaching and detaching the flow channel 120, an exhaust unit 133, a housing 134, an optical portion 135, a filter 136, an optical filter device 600, a light receiving element 137 (detection unit) and the like, a control unit 138 that processes a detected signal and controls the detection unit, a power supply portion 139 that supplies power, and the like. In addition, the optical portion 135 is constituted by a light source 135A that emits light, a beam splitter 135B that reflects light incident from the light source 135A to the sensor chip 110 side and transmits light incident from the sensor chip side to the light receiving element 137 side, and a lens 135C, a lens 135D, and a lens 135E.

In addition, as shown in FIG. 9, the surface of the gas detector 100 is provided with an operation panel 140, a display unit 141, a connection portion 142 for an interface with the outside, and a power supply portion 139. When the power supply portion 139 is a secondary battery, a connection portion 143 for charge may be included.

Further, as shown in FIG. 10, the control unit 138 of the gas detector 100 includes a signal processing unit 144 constituted by a CPU and the like, a light source driver circuit 145 for controlling the light source 135A, a voltage control unit 146 for controlling the wavelength variable interference filter 5 of the optical filter device 600, a light receiving circuit 147 that receives a signal from the light receiving element 137, a sensor chip detection circuit 149 that receives a signal from a sensor chip detector 148 for reading a code of the sensor chip 110 and detecting the presence or absence of the sensor chip 110, an exhaust driver circuit 150 that controls the exhaust unit 133, and the like.

Next, operations of the gas detector 100 as mentioned above will be described below.

The sensor chip detector 148 is provided inside the sensor cover 131 located at the upper portion of the main body 130, and the presence or absence of the sensor chip 110 is detected by the sensor chip detector 148. When a detection signal from the sensor chip detector 148 is detected, the signal processing unit 144 determines that the sensor chip 110 is mounted, and outputs a display signal for displaying an executable detection operation on the display unit 141.

When the operation panel 140 is operated by, for example, a user, and an instruction signal for starting a detection process is output from the operation panel 140 to the signal processing unit 144, first, the signal processing unit 144 causes the light source driver circuit 145 to operate the light source 135A by outputting a light source operation signal. When the light source 135A is driven, stable laser light of linearly polarized light having a single wavelength is emitted from the light source 135A. In addition, the light source 135A has a temperature sensor or a light amount sensor built-in, and its information is output to the signal processing unit 144. When it is determined that the light source 135A is stably operated on the basis of the temperature or the amount of light which is input from the light source 135A, the signal processing unit 144 controls the exhaust driver circuit 150 and brings the exhaust unit 133 into operation. Thereby, a gaseous sample including a target substance (gas molecules) to be detected is induced from the suction port 120A to the suction flow channel 120B, the inside of the sensor chip 110, the exhaust flow channel 120C, and the exhaust port 120D. Meanwhile, the suction port 120A is provided with a dust filter 120A1, relatively large dust particles, some vapor and the like are removed.

In addition, the sensor chip 110 is a sensor, having a plurality of metal nanostructures built-in, in which localized surface plasmon resonance is used. In such a sensor chip 110, an enhanced electric field is formed between metal nanostructures by laser light, and gas molecules gain entrance into the enhanced electric field, Raman scattering light including information of a molecular vibration and Rayleigh scattering light are generated.

The Rayleigh scattering light and the Raman scattering light are incident on the filter 136 through the optical portion 135, the Rayleigh scattering light is split by the filter 136, and the Raman scattering light is incident on the optical filter device 600. The signal processing unit 144 controls the voltage control unit 146, adjusts a voltage applied to the wavelength variable interference filter 5 of the optical filter device 600, and spectroscopically disperses the Raman scattering light corresponding to gas molecules to be detected using the wavelength variable interference filter 5 of the optical filter device 600. Thereafter, when the spectroscopically dispersed light is received in the light receiving element 137, a light receiving signal according to the amount of light received is output to the signal processing unit 144 through the light receiving circuit 147.

The signal processing unit 144 compares spectrum data of the Raman scattering light corresponding to the gas molecules to be detected which are obtained as stated above with data stored in a ROM, determines whether being objective gas molecules, and specifies substances. In addition, the signal processing unit 144 causes the display unit 141 to display result information thereof, or outputs the result information from the connection portion 142 to the outside.

Meanwhile, in FIGS. 9 and 10, the gas detector 100 is illustrated in which the Raman scattering light is spectroscopically dispersed by the wavelength variable interference filter 5 of the optical filter device 600 and a gas is detected from the spectroscopically dispersed Raman scattering light. Besides, the gas detector may be used as a gas detector that specifies a gas type by detecting absorbance inherent in a gas. In this case, a gas sensor that causes a gas to flow into a sensor and detects light absorbed by a gas in the incident light is used as the optical module according to the invention. A gas detector that analyzes and discriminates the gas flowing into the sensor using such a gas sensor is used as the electronic device according to the invention. In such a configuration, it is also possible to detect gas components using the wavelength variable interference filter.

In addition, as a system for detecting the presence of a specific substance, a substance component analyzer such as a noninvasive measurement device of saccharide using near-infrared spectroscopy, or a noninvasive measurement device of information such as food, a living body, and a mineral can be used without being limited to the gas detection as mentioned above.

Hereinafter, a food analyzer will be described as an example of the above-mentioned substance component analyzer.

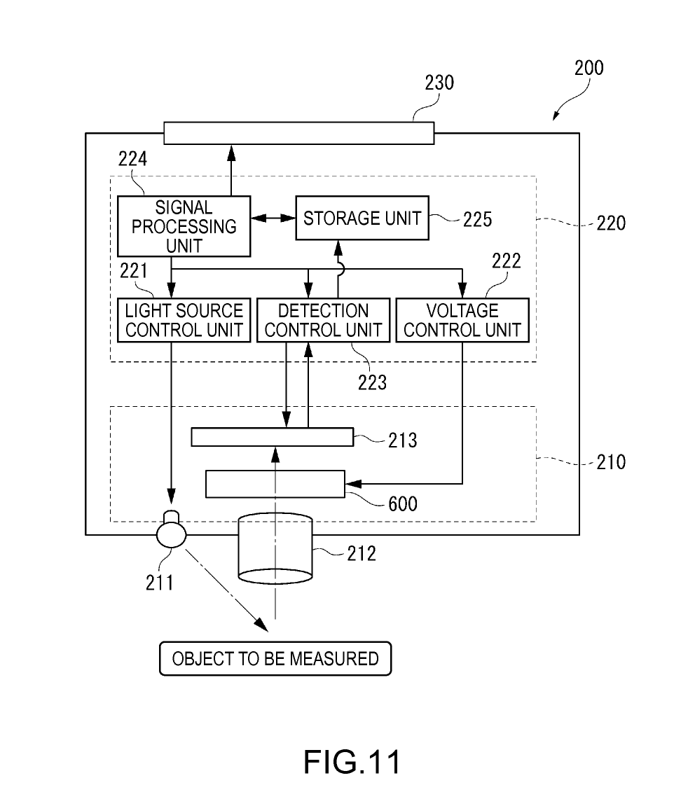

FIG. 11 is a diagram illustrating a schematic configuration of a food analyzer which is an example of the electronic device using the optical filter device 600.

As shown in FIG. 11, the food analyzer 200 includes a detector 210 (optical module), a control unit 220, and a display unit 230. The detector 210 includes a light source 211 that emits light, an imaging lens 212 into which light from an object to be measured is introduced, the optical filter device 600 that spectroscopically disperses light introduced from the imaging lens 212, and an imaging unit 213 (detection unit) that detects spectroscopically dispersed light.

In addition, the control unit 220 includes a light source control unit 221 that performs turn-on and turn-off control of the light source 211 and brightness control at the time of turn-on, a voltage control unit 222 that controls the wavelength variable interference filter 5 of the optical filter device 600, a detection control unit 223 that controls the imaging unit 213 and acquires a spectroscopic image which is imaged by the imaging unit 213, a signal processing unit 224, and a storage unit 225.

The food analyzer 200 is configured such that when the system is driven, the light source 211 is controlled by the light source control unit 221, and light is applied from the light source 211 to an object to be measured. Light reflected from the object to be measured is incident on the optical filter device 600 through the imaging lens 212. In the wavelength variable interference filter 5 of the optical filter device 600, a voltage capable of spectroscopically dispersing a desired wavelength by the control of the voltage control unit 222 is applied, and the spectroscopically dispersed light is imaged by the imaging unit 213 constituted by, for example, a CCD camera or the like. In addition, the imaged light is accumulated in the storage unit 225 as a spectroscopic image. In addition, the signal processing unit 224 changes a voltage value applied to the wavelength variable interference filter 5 by controlling the voltage control unit 222, and acquires a spectroscopic image for each wavelength.

The signal processing unit 224 arithmetically processes data of each pixel in each image accumulated in the storage unit 225, and obtains a spectrum in each pixel. In addition, for example, information on components of food regarding the spectrum is stored in the storage unit 225. The signal processing unit 224 analyzes data of the obtained spectrum on the basis of the information on the food stored in the storage unit 225, and obtains food components included in the object to be detected and the content thereof. In addition, food calorie, freshness and the like can be calculated from the obtained food components and content. Further, by analyzing a spectral distribution within the image, it is possible to extract a portion in which freshness deteriorates in food to be tested, and to detect foreign substances or the like included in the food.

The signal processing unit 224 performs a process of displaying information such as the components, the content, calorie, freshness and the like of the food to be tested which are obtained as mentioned above, on the display unit 230.

In addition, in FIG. 11, an example of the food analyzer 200 is illustrated, but the food analyzer can also be used as the above-mentioned noninvasive measurement device of other information using substantially the same configuration. For example, the food analyzer can be used as a living body analyzer that analyzes living body components, for example, measures and analyzes body fluid components such as blood. Such a living body analyzer is used as a device that measures, for example, body fluid components such as blood. When the analyzer is used as a device that detects ethyl alcohol, the analyzer can be used as an anti-drunk-driving device that detects the drinking condition of a driver. In addition, the analyzer can also be used as an electronic endoscope system including such as living body analyzer.

Further, the analyzer can also be used as a mineral analyzer that performs a component analysis of a mineral.

Further, the wavelength variable interference filter, the optical module, and the electronic device according to the invention can be applied to the following devices.

For example, it is also possible to transmit data using the light of each wavelength by temporally changing the intensity of the light of each wavelength. In this case, light of a specific wavelength is spectroscopically dispersed by the wavelength variable interference filter provided in the optical module, and is received in the light receiving unit, thereby allowing data transmitted by the light of a specific wavelength to be extracted. The data of the light of each wavelength is processed by the electronic device including such an optical module for data extraction, and thus it is also possible to perform optical communication.

In addition, the electronic device can also be applied to a spectroscopic camera, a spectroscopic analyzer and the like that image a spectroscopic image by spectroscopically dispersing light using the wavelength variable interference filter included in the optical filter device according to the invention. An example of such a spectroscopic camera includes an infrared camera having a wavelength variable interference filter built-in.

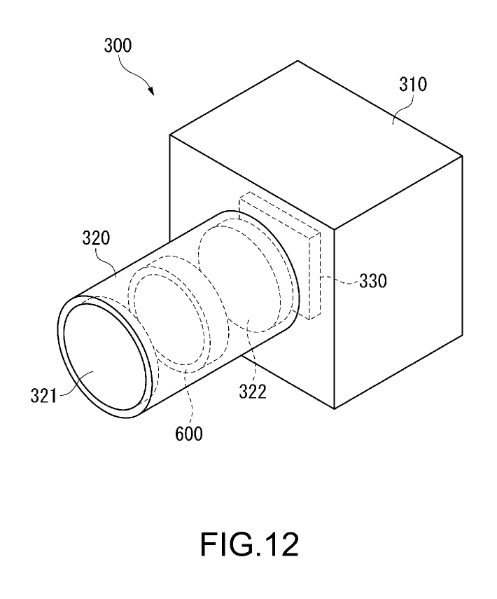

FIG. 12 is a schematic diagram illustrating a schematic configuration of a spectroscopic camera. As shown in FIG. 12, a spectroscopic camera 300 includes a camera body 310, an imaging lens unit 320, and an imaging unit 330 (detection unit).

The camera body 310 is a portion which is held and operated by a user.

The imaging lens unit 320 is provided in the camera body 310, and guides incident image light to the imaging unit 330. In addition, as shown in FIG. 12, the imaging lens unit 320 includes an objective lens 321, an imaging lens 322, and the optical filter device 600 which is provided between these lenses.

The imaging unit 330 is constituted by a light receiving element, and images image light guided by the imaging lens unit 320.

In such a spectroscopic camera 300, it is possible to image a spectroscopic image of light having a desired wavelength by transmitting light of a wavelength serving as an imaging object using the wavelength variable interference filter 5 of the optical filter device 600.

Further, the wavelength variable interference filter included in the optical filter device according to the invention may be used as a band pass filter, and may be used, as for example, an optical laser device in which only narrow-band light centered on a predetermined wavelength in light of a predetermined wavelength region which is emitted by the light-emitting element is spectroscopically dispersed and transmitted using the wavelength variable interference filter.

In addition, the wavelength variable interference filter included in the optical filter device according to the invention may be used as a living body authentication device, and may also be applied to, for example, an authentication device of a blood vessel, a fingerprint, a retina, an iris and the like using light of a near-infrared region or a visible region.

Further, the optical module and the electronic device can be used as a concentration detector. In this case, infrared energy (infrared light) emitted from a substance is spectroscopically dispersed and analyzed by the wavelength variable interference filter, and the concentration of a test object in a sample is measured.

As described above, the optical filter device and the electronic device according to the invention can also be applied to any device that spectroscopically disperses predetermined light from incident light. As described above, since the above-mentioned optical filter device can spectroscopically disperse a plurality of wavelengths using one device, it is possible to accurately perform the measurement of a spectrum of a plurality of wavelengths, and the detection of a plurality of components. Therefore, as compared to a device of the related art that extracts a desired wavelength using a plurality of devices, the optical filter device can promote a reduction in the size of the optical module or the electronic device, and can be suitably used in, for example, a portable or in-car electronic device.

In the above-mentioned descriptions of the colorimeter 1, the gas detector 100, the food analyzer 200, and the spectroscopic camera 300, an example is illustrated in which the optical filter device 600 of the first embodiment is applied, but there is no limitation thereto. The optical filter devices of other embodiments can also be applied to the colorimeter 1 or the like similarly.

Besides, a specific structure at the time of carrying out the invention may be configured by appropriately combining each of the above-mentioned embodiments and modification examples in a range capable of achieving the object of the invention, and may be appropriately changed to other structures or the like.

The entire disclosure of Japanese Patent Application No. 2013-201048, filed Sep. 27, 2013 is expressly incorporated by reference herein.

What is claimed is:

1. An optical filter device comprising:
an interference filter that includes a first reflective film and a second reflective film facing the first reflective film;
a housing that stores the interference filter; and
a bonding member that fixes the interference filter to the housing,
wherein the housing includes a first surface which is located so as to face one surface of the interference filter, a second surface which is continuous with the first surface, the second surface is located so as to face another surface intersecting the one surface of the interference filter, and a third surface which is continuous from the first surface, the third surface is located in a direction away from the interference filter, and
the bonding member is disposed between the one surface and the first surface, and between the another surface and the second surface.

2. The optical filter device according to claim 1, wherein the housing includes a groove portion that surrounds a portion of a periphery of the first surface, and
the third surface is a lateral side on the first surface side in the groove portion.

3. The optical filter device according to claim 2, wherein a distance between the one surface and a bottom of the groove portion is larger than a distance between the another surface and the second surface.

4. The optical filter device according to claim 1, wherein the another surface includes a first lateral side having a planar shape and a second lateral side having a planar shape, continuous with the first lateral side, which intersects the first lateral side, and
the bonding member is provided extending over the first lateral side and the second lateral side.

5. The optical filter device according to claim 1, wherein the interference filter includes a first substrate which is provided with the first reflective film and a second substrate, facing the first substrate, which is provided with the second reflective film, and
the bonding member fixes any of the first substrate and the second substrate to the housing.

6. The optical filter device according to claim 5, wherein any one of the first substrate and the second substrate includes a protruding portion that protrudes to the other substrate in a planar view when seen from a direction from the first substrate toward the second substrate, and
the first surface overlaps at least a portion of the protruding portion in the planar view.

7. The optical filter device according to claim 6, wherein the protruding portion includes a connection terminal which is electrically connected to a terminal on the housing side provided to the housing.

8. The optical filter device according to claim 5, wherein the second substrate includes a movable portion which is provided with the second reflective film and a holding portion that replaceably holds the movable portion in a thickness direction of the second substrate, and
the bonding member fixes the first substrate to the housing.

9. An optical module comprising:
an interference filter that includes a first reflective film and a second reflective film facing the first reflective film;
a housing that stores the interference filter;
a bonding member that fixes the interference filter to the housing; and
a detection unit that detects light extracted by the interference filter,
wherein the housing includes a first surface which is located so as to face one surface of the interference filter, a second surface which is continuous with the first surface, the second surface is located so as to face another surface intersecting the one surface of the interference filter, and a third surface which is continuous from the first surface, the third surface is located in a direction away from the interference filter, and
the bonding member is disposed between the one surface and the first surface, and between the another surface and the second surface.

10. An electronic device comprising:
an interference filter that includes a first reflective film and a second reflective film facing the first reflective film;
a housing that stores the interference filter;
a bonding member that fixes the interference filter to the housing; and
a control unit that controls the interference filter,
wherein the housing includes a first surface which is located so as to face one surface of the interference filter, a second surface which is continuous with the first surface, the second surface is located so as to face another surface intersecting the one surface of the interference filter, and a third surface which is continuous from the first surface, the third surface is located in a direction away from the interference filter, and
the bonding member is disposed between the one surface and the first surface, and between the another surface and the second surface.

11. A MEMS device comprising:
a MEMS element;
a housing that stores the MEMS element; and
a bonding member that fixes the substrate to the housing,
wherein the housing includes a first surface which is located so as to face one surface of the MEMS element, a second surface which is continuous with the first surface, the second surface is located so as to face another surface intersecting the one surface of the MEMS element, and a third surface which is continuous from the first surface, the third surface is located in a direction away from the MEMS element, and
the bonding member is disposed between the one surface and the first surface, and between the another surface and the second surface.
